(19) United States
(12) Patent Application Publication
(10) Pub. No.: US 2022/0085062 A1
(43) Pub. Date: Mar. 17, 2022

(54) SEMICONDUCTOR MEMORY DEVICE

(71) Applicant: Kioxia Corporation, Tokyo (JP)

(72) Inventors: Wataru UNNO, Kuwana (JP); Takuya NISHIKAWA, Yokkaichi (JP); Jun TAKEKIDA, Yokkaichi (JP); Kazuhiro NAKANISHI, Yokkaichi (JP)

(73) Assignee: Kioxia Corporation, Tokyo (JP)

(21) Appl. No.: 17/199,878

(22) Filed: Mar. 12, 2021

(30) Foreign Application Priority Data
Sep. 14, 2020 (JP) 2020-153459

(51) Int. Cl. H01L 27/11582; H01L 23/522; H01L 27/11556

(52) U.S. Cl. CPC H01L 27/11582; H01L 27/11556; H01L 23/5226

(57) ABSTRACT

According to one embodiment, a semiconductor memory device includes a pair of first plate-shaped portions that extends in a stacking direction of respective layers of a first stacked body and a first direction crossing the stacking direction, and is in contact with a second stacked body on both sides of the second stacked body in a second direction crossing the stacking direction and the first direction, a pair of second plate-shaped portions of which longitudinal direction is in the first direction, the pair of second plate-shaped portions extending through the first stacked body in the stacking direction on both sides of the pair of first plate-shaped portions in the second direction in positions apart from the pair of first plate-shaped portions, and a columnar portion that extends through the first stacked body in the stacking direction in a position between one of the first plate-shaped portions out of the pair of first plate-shaped portions and one of the second plate-shaped portions, that faces the one of the first plate-shaped portions, out of the pair of second plate-shaped portions, and includes a first material having a high ultraviolet-light blocking capability.

### CROSS-REFERENCE TO RELATED APPLICATIONS

This application is based upon and claims the benefit of priority from Japanese Patent Application No. 2020-153459, filed on Sep. 14, 2020; the entire contents of which are incorporated herein by reference.

### FIELD

Embodiments described herein relate generally to a semiconductor memory device.

### BACKGROUND

In manufacturing processes of a three-dimensional nonvolatile memory, a plurality of insulating layers, for example, is replaced with conductive layers, and a stacked body of conductive layers is formed. In order to pass a contact connecting upper and lower structures of the stacked body, for example, a part of the stacked body is left in the state of an insulating layer without being replaced with a conductive layer.

### BRIEF DESCRIPTION OF THE DRAWINGS

FIGS. 1A and 1B are schematic views illustrating a configuration example of a semiconductor memory device according to a first embodiment;

FIGS. 2A to 2C are sectional views of the semiconductor memory device according to the first embodiment, taken along a Y direction;

FIGS. 3A to 3C are cross-sectional views of the semiconductor memory device according to the first embodiment;

FIGS. 4A and 4B are sectional views illustrating an example of a procedure for a manufacturing method of the semiconductor memory device according to the first embodiment;

FIGS. 5A and 5B are sectional views illustrating the example of the procedure for the manufacturing method of the semiconductor memory device according to the first embodiment;

FIGS. 6A and 6B are sectional views illustrating the example of the procedure for the manufacturing method of the semiconductor memory device according to the first embodiment;

FIGS. 7A and 7B are sectional views illustrating the example of the procedure for the manufacturing method of the semiconductor memory device according to the first embodiment;

FIGS. 8A and 8B are sectional views illustrating the example of the procedure for the manufacturing method of the semiconductor memory device according to the first embodiment;

FIGS. 9A and 9B are sectional views illustrating the example of the procedure for the manufacturing method of the semiconductor memory device according to the first embodiment;

FIGS. 10A and 10B are sectional views illustrating the example of the procedure for the manufacturing method of the semiconductor memory device according to the first embodiment;

FIGS. 11A and 11B are sectional views illustrating the example of the procedure for the manufacturing method of the semiconductor memory device according to the first embodiment;

FIGS. 12A and 12B are sectional views illustrating the example of the procedure for the manufacturing method of the semiconductor memory device according to the first embodiment;

FIGS. 13A and 13B are sectional views illustrating the example of the procedure for the manufacturing method of the semiconductor memory device according to the first embodiment;

FIGS. 14A and 14B are sectional views illustrating the example of the procedure for the manufacturing method of the semiconductor memory device according to the first embodiment;

FIGS. 15A and 15B are sectional views illustrating the example of the procedure for the manufacturing method of the semiconductor memory device according to the first embodiment;

FIGS. 16A and 16B are sectional views illustrating the example of the procedure for the manufacturing method of the semiconductor memory device according to the first embodiment;

FIGS. 17A and 17B are sectional views illustrating the example of the procedure for the manufacturing method of the semiconductor memory device according to the first embodiment;

FIGS. 18A and 18B are sectional views illustrating the example of the procedure for the manufacturing method of the semiconductor memory device according to the first embodiment;

FIGS. 19A and 19B are sectional views illustrating the example of the procedure for the manufacturing method of the semiconductor memory device according to the first embodiment;

FIGS. 20A and 20B are cross-sectional views illustrating the example of the procedure for the manufacturing method of the semiconductor memory device according to the first embodiment;

FIGS. 21A and 21B are sectional views illustrating the example of the procedure for the manufacturing method of the semiconductor memory device according to the first embodiment;

FIGS. 22A and 22B are cross-sectional views illustrating the example of the procedure for the manufacturing method of the semiconductor memory device according to the first embodiment;

FIGS. 23A to 23C are sectional views of a semiconductor memory device according to a second embodiment, taken along the Y direction;

FIGS. 24A to 24C are cross-sectional views of the semiconductor memory device according to the second embodiment;

FIGS. 25A and 25B are sectional views illustrating an example of a procedure for a manufacturing method of the semiconductor memory device according to the second embodiment;

FIGS. 26A and 26B are sectional views illustrating the example of the procedure for the manufacturing method of the semiconductor memory device according to the second embodiment;

FIGS. 27A and 27B are sectional views illustrating the example of the procedure for the manufacturing method of the semiconductor memory device according to the second embodiment;

FIGS. 28A and 28B are sectional views illustrating the example of the procedure for the manufacturing method of the semiconductor memory device according to the second embodiment; and

FIGS. 29A and 29B are sectional views illustrating the example of the procedure for the manufacturing method of the semiconductor memory device according to the second embodiment.

### DETAILED DESCRIPTION

In general, according to one embodiment, a semiconductor memory device includes: a first stacked body in which a plurality of first conductive layers is stacked with a first insulating layer interposed; a second stacked body in which a plurality of second insulating layers is stacked with the first insulating layer interposed, the second stacked body being surrounded by the first stacked body as seen from a stacking direction of respective layers of the first stacked body; a pair of first plate-shaped portions extending in the stacking direction and a first direction crossing the stacking direction, the pair of first plate-shaped portions being in contact with the second stacked body on both sides of the second stacked body in a second direction crossing the stacking direction and the first direction; a pair of second plate-shaped portions of which longitudinal direction is in the first direction, the pair of second plate-shaped portions sandwiching the pair of first plate-shaped portions in the second direction in positions apart from the pair of first plate-shaped portions, and extending through the first stacked body in the stacking direction; a first columnar portion extending through the first stacked body in the stacking direction in a position between the pair of second plate-shaped portions apart from the pair of first plate-shaped portions in the first direction, and forming memory cells at intersections with at least a part of the plurality of first conductive layers, respectively; a second columnar portion extending through at least one of the first stacked body and the second stacked body in the stacking direction in a position between the pair of second plate-shaped portions arranged on both sides of the pair of first plate-shaped portions in the second direction, the second columnar portion including an insulating material; and a third columnar portion extending through the first stacked body in the stacking direction in a position between one of the first plate-shaped portions out of the pair of first plate-shaped portions and one of the second plate-shaped portions, that faces the one of the first plate-shaped portions, out of the pair of second plate-shaped portions, the third columnar portion including a first material that has a higher ultraviolet-light blocking capability than an ultraviolet-light blocking capability of the insulating material.

Exemplary embodiments of the present invention will be explained below in detail with reference to the accompanying drawings. The present invention is not limited to the following embodiments. Meanwhile, constituent elements in the following embodiments include ones that can be easily conceived of by the skilled person in the art or ones that are substantially identical thereto.

### First Embodiment

Hereinafter, a first embodiment will be described in detail with reference to the drawings.

(Configuration Example of Semiconductor Memory Device)

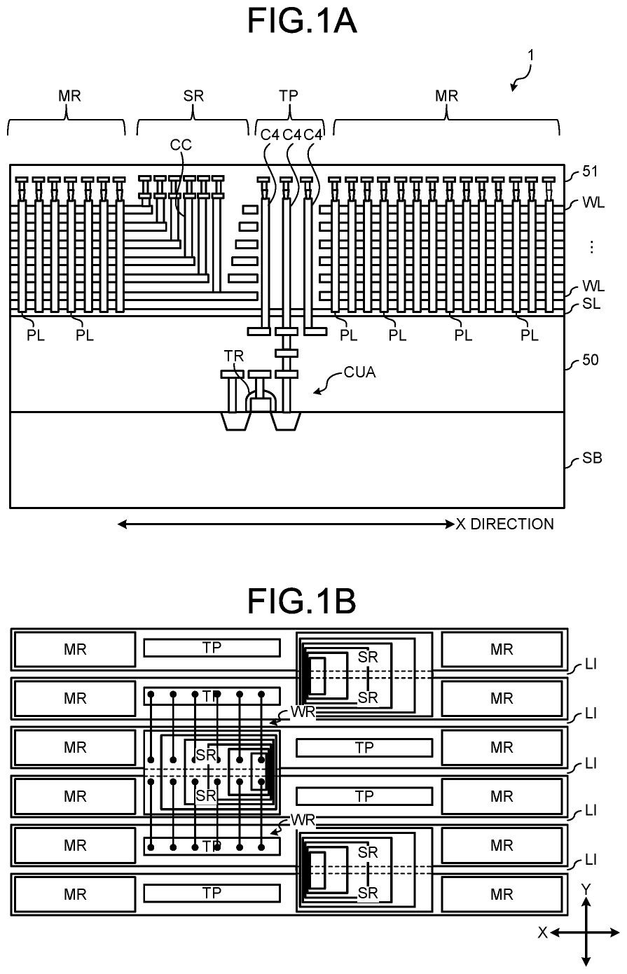

FIGS. 1A and 1B are schematic views illustrating a configuration example of a semiconductor memory device 1 according to the first embodiment. FIG. 1A is a sectional view of the semiconductor memory device 1, taken along an X direction, and FIG. 1B is a schematic plan view illustrating a layout of the semiconductor memory device 1. Note that hatching is omitted in FIG. 1A in view of visibility of the drawing. Further, some of upper-layer wirings is omitted in FIGS. 1A and 1B.

Meanwhile, in the present specification, both of the X direction and the Y direction are directions along a surface of a word line WL to be described later, and the X direction and the Y direction are perpendicular to each other. Further, an electrical leading direction of the word line WL to be described later will be occasionally referred to as a first direction, and the first direction is a direction along the X direction. Moreover, a direction crossing the first direction will be occasionally referred to as a second direction, and the second direction is a direction along the Y direction. However, because of possible manufacturing differences in the semiconductor memory device 1, the first direction and the second direction are not necessarily perpendicular to each other.

As illustrated in FIGS. 1A and 1B, the semiconductor memory device 1 includes a peripheral circuit CUA, a memory region MR, a through contact region TP, and a staircase region SR on a substrate SB.

The substrate SB is a semiconductor substrate such as a silicon substrate, for example. On the substrate SB, the peripheral circuit CUA including a transistor TR, a wiring, and the like is arranged.

The peripheral circuit CUA contributes to operations of memory cells to be described later. The peripheral circuit CUA is covered with an insulating layer 50. On the insulating layer 50, a source line SL is arranged. Above the source line SL, a plurality of word lines WL is stacked.

The plurality of word lines WL is each divided in the Y direction by a plurality of contacts LI that penetrates the word lines WL in a stacking direction and extend in the X direction.

Between the plurality of contacts LI, a plurality of memory regions MR, together with the staircase region SR and the through contact region TP that are interposed between the plurality of memory regions MR, are arranged so as to be arrayed in the X direction.

In the memory region MR, a plurality of pillars PL penetrating the word lines WL in the stacking direction is arranged. At the intersections of the pillars PL and the word lines WL, a plurality of memory cells is formed. As a result of this, the semiconductor memory device 1 is configured as a three-dimensional nonvolatile memory in which memory cells are three-dimensionally arranged in the memory regions MR, for example.

The staircase region SR has a shape in which the plurality of word lines WL is so recessed down in the stacking direction as to be shaped like a mortar. More specifically, the staircase region SR has a shape of a mortar that descends in steps from both sides in the X direction and one of sides in the Y direction toward a bottom surface. The other of the sides in the Y direction is open. Each of the steps is formed of the word line WL in each layer. The word line WL in each layer keeps electrical conduction between both sides in the X direction with the staircase region SR interposed, via a stepped portion on one of the sides in the Y direction.

In the stepped portions on both sides in the X direction, a contact CC connecting the word line WL in each layer and an upper-layer wiring WR or the like is arranged on a terrace in each of the steps on one of the sides in the X direction closer to the memory region MR adjacent to the staircase region SR.

Thus, the word lines WL that are stacked to form a multilayered structure can be individually led. Specifically, a writing voltage, a reading voltage, and the like are applied to the memory cells in the memory regions MR on both sides in the X direction via the word lines WL at the same height positions as the memory cells, respectively, from the contacts CC.

Additionally, in the present specification, a direction in which a terrace surface of each step of the staircase region SR faces is defined as an upward direction.

The through contact region TP not including the word lines WL is arranged on the other of the sides in the X direction with respect to the staircase region SR. In the through contact region TP, a contact C4 is arranged to connect the peripheral circuit CUA arranged on the substrate SB located on a lower side and the upper-layer wiring WR or the like connected to the contact CC in the staircase region SR. Various kinds of voltages to be applied to the memory cell from the contact CC are controlled by the peripheral circuit CUA via the contact C4, the upper-layer wiring WR, and the like.

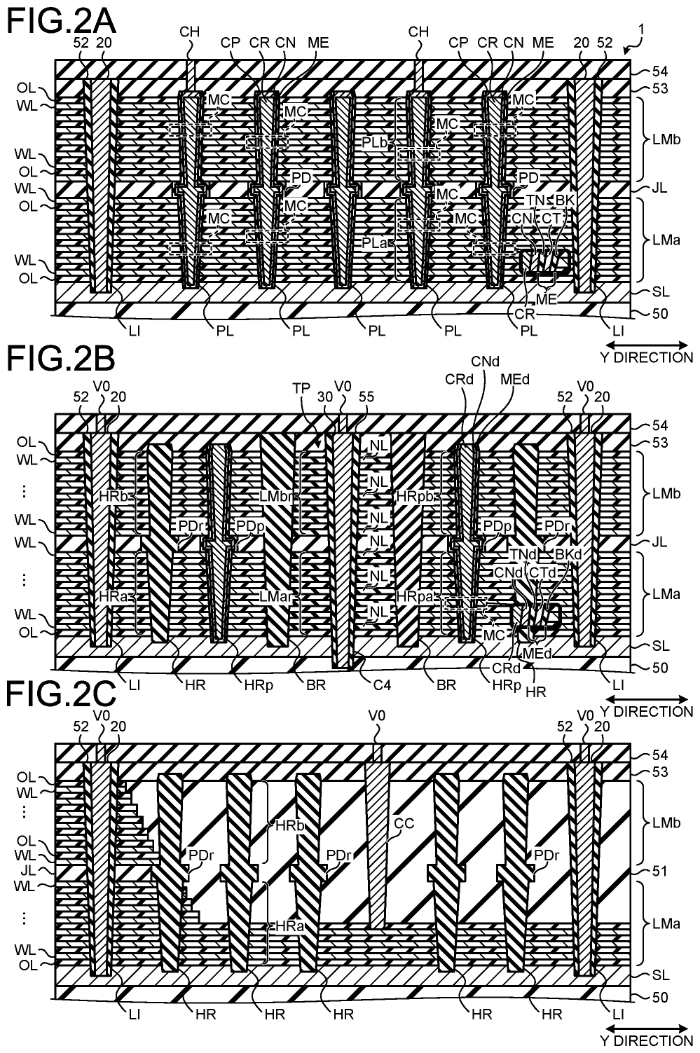

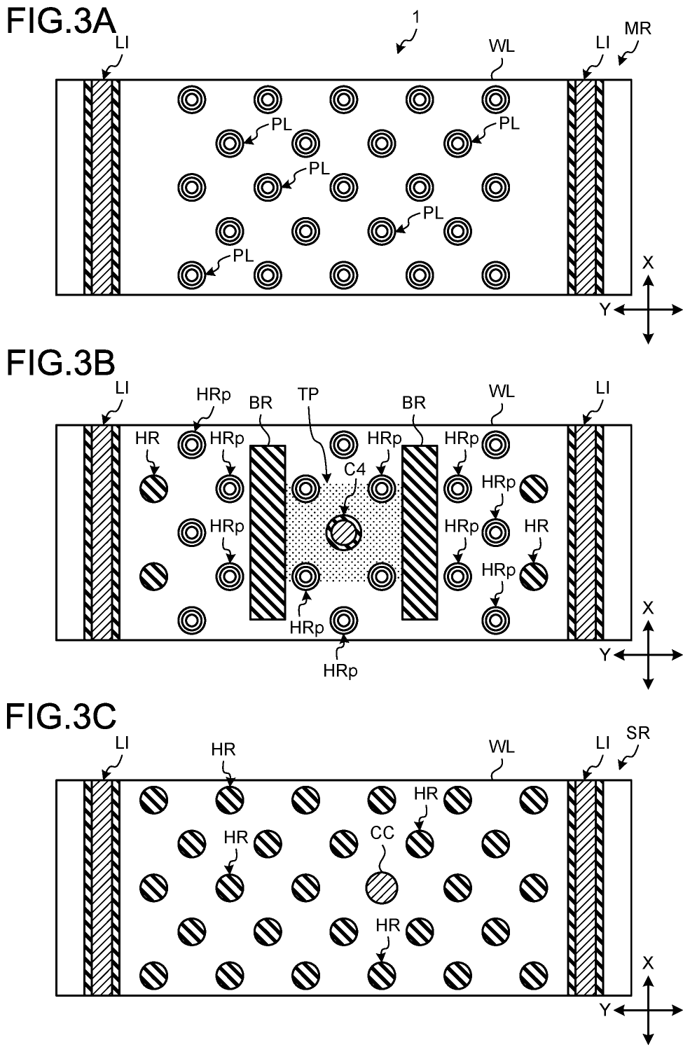

Next, details of the configuration example of the semiconductor memory device 1 will be provided with reference to FIGS. 2A to 3C.

FIGS. 2A to 2C are sectional views of the semiconductor memory device 1 according to the first embodiment, taken along the Y direction. FIG. 2A is a sectional view of the memory region MR, FIG. 2B is a sectional view of a region in the vicinity of the through contact region TP, and FIG. 2C is a sectional view of the staircase region SR. Note that the structures under the insulating layer 50, such as the substrate SB and the peripheral circuit CUA, an upper-layer wiring, and the like are omitted in FIGS. 2A to 2C.

FIGS. 3A to 3C are cross-sectional views of the semiconductor memory device 1 according to the first embodiment. More specifically, FIGS. 3A to 3C are cross-sectional views taken transversely at the height position of the word line WL connected to the contact CC in a position illustrated in FIG. 2C in the staircase region SR, among the plurality of word lines WL included in the semiconductor memory device 1. FIG. 3A is a cross-sectional view of the memory region MR, FIG. 3B is a cross-sectional view of a region in the vicinity of the through contact region TP, and FIG. 3C is a cross-sectional view of the staircase region SR.

As illustrated in FIGS. 2A to 2C and FIGS. 3A to 3C, the semiconductor memory device 1 includes stacked bodies LMa and LMb arranged on the source line SL, for example, an insulating layer 53 covering the stacked bodies LMa and LMb, and an insulating layer 54 covering the insulating layer 53. The source line SL is a polysilicon layer or the like, for example.

Each of the stacked bodies LMa and LMb as a first stacked body has a configuration in which the word lines WL as first conductive layers and insulating layers OL as first insulating layers are alternately stacked. The stacked body LMa is arranged on the source line SL. The stacked body LMb is arranged on the stacked body LMa with a junction layer JL interposed. The word lines WL are tungsten layers, molybdenum layers, or the like, for example. The insulating layers OL and the junction layer JL are SiO₂ layers or the like, for example.

Additionally, although each of the stacked bodies LMa and LMb includes seven word lines WL in the example illustrated in FIGS. 2A to 2C, the number of layers of the word lines WL can be set to any number. Further, the stacked body LMa may be configured so as to include a selection gate line (not illustrated) arranged under the word line WL in the lowermost layer. Alternatively, the stacked body LMb may be configured so as to include a selection gate line (not illustrated) arranged above the word line WL in the uppermost layer.

The stacked bodies LMa and LMb include the memory region MR in which the memory cells MC are three-dimensionally arranged, and the staircase region SR in which the word lines WL in respective layers are stepped. Further, the stacked bodies LMa and LMb surround the through contact region TP in which the contact C4 connected to the peripheral circuit CUA is arranged.

The stacked bodies LMa and LMb are each divided by the contacts LI extending in the X direction, while including the through contact region TP. The memory region MR, the through contact region TP, and the staircase region SR are partitioned into a plurality of regions called blocks by the plurality of contacts LI arranged in the Y direction.

The contact LI as a second plate-shaped portion penetrates the insulating layer 53, the stacked bodies LMa and LMb, and the junction layer JL in a stacking direction of the stacked bodies LMa and LMb, and reaches the source line SL. Each of the contacts LI includes an insulating layer 52 covering a sidewall of the contact LI. A region on the inner side of the insulating layer 52 is filled with a conductive layer 20. The insulating layer 52 is a SiO₂ layer or the like, for example. The conductive layer 20 is a polysilicon layer, a tungsten layer, or the like, for example. The conductive layer 20 in the contact LI is connected to an upper-layer wiring via a plug V0 penetrating the insulating layer 54.

Each of the contacts LI functions as a source-line contact, for example, because of inclusion of the conductive layer 20 connected to the plug V0 and its position on the source line SL. Alternatively, in place of the contact LI, a plate-shaped structure filled with an insulating layer such as a SiO₂ layer may divide the stacked bodies LMa and LMb in the Y direction.

Further, in the memory region MR of the stacked body LMb, an insulating member (not illustrated) extending in the X direction above the word line WL in the uppermost layer is arranged. The insulating member is arranged an upper portions of each of central pillars PL, for example, among the pillars PL arranged in the Y direction in each of the blocks partitioned by the contacts LI so as to cross the central pillars PL. The insulating member is interposed between selection gate lines (not illustrated) adjacent to each other in the Y direction above the stacked body LMb. The insulating member partitions the conductive layer above the word line WL in the uppermost layer, for example, in a pattern of the selection gate lines.

As illustrated in FIGS. 2A and 3A, in the memory region MR, the plurality of pillars PL is arranged in a matrix between two contacts LI in the stacked bodies LMa and LMb. Each of the pillars PL extends from a lower portion of the insulating layer 53, penetrates the stacked bodies LMa and LMb and the junction layer JL in the stacking direction of the stacked bodies LMa and LMb, and reaches the source line SL.

The pillar PL as a first columnar portion has a shape in which a pillar PLa penetrating the stacked body LMa and a pillar PLb penetrating the stacked body LMb are joined at the height position of the junction layer JL. The pillars PLa and PLb can each have a tapered profile in which a diameter of a bottom surface is smaller than a diameter of an upper surface, a bowing profile in which a diameter at a predetermined height position between the upper surface and the bottom surface is increased, or the like, for example.

Each of the pillars PL includes a pedestal PD at a junction portion in the junction layer JL. The pedestal PD has a diameter larger than the diameter of the upper surface of the pillar PLa arranged in the stacked body LMa. Further, each of the pillars PL includes a cap layer CP in an upper end of the pillar PLb. The cap layer CP has a diameter approximately equal to an outer diameter of a later-described core layer CR of the pillar PL, and covers at least a part of an upper surface of the pillar PL.

Each of the pillars PLa and PLb and the pedestal PD includes a memory layer ME, a channel layer CN, and the core layer CR arranged in this order from an outer periphery thereof. The channel layer CN is arranged also in a bottom of the pillar PLa to be connected to the source line SL, and is further connected to the above-described cap layer CP. The memory layer ME is a layer in which a block insulating layer BK, a charge storage layer CT, and a tunnel insulating layer TN are stacked in this order from the outer periphery of each of the pillars PLa and PLb and the pedestal PD.

The block insulating layer BK, the tunnel insulating layer TN, and the core layer CR are SiO₂ layers or the like, for example. The charge storage layer CT is a SiN layer or the like, for example. The channel layer CN and the cap layer CP are amorphous silicon layers, polysilicon layers, or the like, for example.

The cap layer CP of the pillar PL is connected to an upper-layer wiring such as a bit line via a plug CH penetrating the insulating layers 53 and 54. Each of the pillars PL includes the memory layer ME and the channel layer CN, thereby forming the plurality of memory cells MC at respective intersections of the pillars PL and the word lines WL.

However, the pillar PL that has the above-described insulating member arranged thereon, like a central pillar PL among five pillars PL arranged between two contacts LI, for example, does not include the plug CH. That kind of pillar PL is arranged in order to keep a regular array of the plurality of pillars PL. No memory cell is formed on a side surface of such a pillar, or the memory-cell function of such a pillar is ineffective.

As illustrated in FIGS. 2B and 3B, the through contact region TP is surrounded by the stacked bodies LMa and LMb and includes stacked bodies LMar and LMbr each including insulating layers NL in place of the word lines WL included in the stacked bodies LMa and LMb.

In other words, each of the stacked bodies LMar and LMbr as a second stacked body has a configuration in which the insulating layers OL and the insulating layers NL as second insulating layers are alternately stacked. The insulating layers NL are SiN layers or the like, for example.

The number of the insulating layers NL forming each of the stacked bodies LMar and LMbr, and their height positions, are equal to the number of the word lines WL forming each of the stacked bodies LMa and LMb, and their height positions, respectively, for example. The number of the insulating layers OL forming each of the stacked bodies LMar and LMbr, and their height positions, are equal to the number of the insulating layers OL forming each of the stacked bodies LMa and LMb, and their height positions, respectively, for example. The junction layer JL is interposed between the stacked bodies LMar and LMbr at the same height positions as the height position of the junction layer JL between the stacked bodies LMa and LMb.

In the through contact region TP, the contact C4 is arranged to penetrate the insulating layer 53, the stacked bodies LMar and LMbr, the junction layer JL, and the source line SL in a stacking direction, and is electrically connected to the transistor TR (refer to FIG. 1A) or the like included in the peripheral circuit CUA on the substrate SB.

The contact C4 includes an insulating layer 55 covering a sidewall of the contact C4 and a conductive layer 30 filled in the inner side of the insulating layer 55. The insulating layer 55 is a SiO₂ layer or the like, for example. The conductive layer 30 is a tungsten layer or the like, for example. The conductive layer 30 in the contact C4 is connected to an upper-layer wiring via the plug V0 penetrating the insulating layer 54.

The stacked bodies LMar and LMbr are mainly configured with the insulating layers NL and OL. Thus, in spite of arrangement of the contact C4 penetrating the stacked bodies LMar and LMbr, it is possible to suppress electrical conduction with the word lines WL of the stacked bodies LMa and LMb surrounding the through contact region TP, occurrence of leakage currents, and the like.

Meanwhile, although FIGS. 2B and 3B do not provide for the sake of simplicity, a plurality of contacts C4 (refer to FIG. 1A) may be arranged in the through contact region TP in some cases. Also in such cases, arranging the stacked bodies LMar and LMbr configured with the insulating layers NL and OL between the plurality of contacts C4 can suppress electrical conduction between the plurality of contacts C4, occurrence of leakage currents, and the like.

The contact C4 includes a liner of the insulating layer 55 around the conductive layer 30. This further suppresses electrical conduction with the word lines WL and between the plurality of contacts C4, and occurrence of leakage currents.

Plate-shaped portions BR extending in the X direction are arranged in contact with the stacked bodies LMar and LMbr on both sides of the through contact region TP in the Y direction. In other words, the stacked bodies LMa and LMb surrounding the through contact region TP are separated from the stacked bodies LMar and LMbr at least in the Y direction by the plate-shaped portions BR.

The plate-shaped portion BR as first plate-shaped portions penetrates the insulating layer 53, boundaries between the stacked bodies LMa and LMb and the stacked bodies LMar and LMbr, and the junction layer JL in the stacking direction of the stacked bodies LMa and LMb, and reaches the source line SL. The inner side of each of the plate-shaped portions BR is filled with an insulating layer, for example. As will be described later, the plate-shaped portions BR inhibit replacement of the insulating layers NL with the word lines WL that is to be performed in manufacturing processes of the semiconductor memory device 1, in the through contact region TP.

A plurality of columnar portions HR and HRp is arranged in a matrix in a region including the through contact region TP and the vicinity of the through contact region TP.

The columnar portion HR as a second columnar portion is at least arranged adjacently to the contact LI. In other words, in a plurality of arrays of the columnar portions HR and HRp arranged along the contact LI and the plate-shaped portion BR in the Y direction, one row closest to the contact LI includes the columnar portions HR.

The columnar portion HR extends from a lower portion of the insulating layer 53, penetrates the stacked bodies LMa and LMb, and the junction layer JL in the stacking direction of the stacked bodies LMa and LMb, and reaches the source line SL.

More specifically, the columnar portion HR has a shape in which a columnar portion HRa penetrating the stacked body LMa and a columnar portion HRb penetrating the stacked body LMb are joined at the height position of the junction layer JL. An upper end of the columnar portion HRb protrudes into a lower portion of the insulating layer 53. The columnar portions HRa and HRb can each have a tapered profile in which a diameter of a bottom surface is smaller than a diameter of an upper surface, a bowing profile in which a diameter at a predetermined height position between an upper surface and a bottom surface is increased, or the like, for example.

Each of the columnar portions HR includes a pedestal PDr at a junction portion in the junction layer JL. The pedestal PDr has a diameter larger than a diameter of an upper surface of the columnar portion HRa arranged in the stacked body LMa.

The columnar portions HRa and HRb and the pedestal PDr are filled with an insulating layer as an insulating material. The insulating layer is a SiO₂ layer or the like, for example.

The columnar portion HRp as a third columnar portion is at least arranged adjacently to the plate-shaped portions BR. In other words, in the plurality of arrays of the columnar portions HR and HRp arranged along the contact LI and the plate-shaped portion BR in the Y direction, one row closest to the plate-shaped portion BR includes the columnar portions HRp.

In the plurality of arrays of the columnar portions HR and HRp arranged along the contact LI and the plate-shaped portion BR in the Y direction, other rows except the row closest to the contact LI may include the columnar portions HRp. Further, the columnar portions HRp may be arranged in a region sandwiched between two plate-shaped portions BR.

The columnar portion HRp extends from a lower portion of the insulating layer 53, penetrates the stacked bodies LMa and LMb and the junction layer JL in the stacking direction of the stacked bodies LMa and LMb, and reaches the source line SL. The columnar portion HRp arranged between two plate-shaped portions BR may extend either through boundaries between the stacked bodies LMa and LMb and the stacked bodies LMar and LMbr or through the stacked bodies LMar and LMbr, in the stacking direction of the stacked bodies LMar and LMbr.

More specifically, the columnar portion HRp has a shape in which a columnar portion HRpa penetrating the stacked body LMa or the like and a columnar portion HRpb penetrating the stacked body LMb or the like are joined at the height position of the junction layer JL. An upper end of the columnar portion HRpb protrudes into a lower portion of the insulating layer 53. The columnar portions HRpa and HRpb can each have a tapered profile in which a diameter of a bottom surface is smaller than a diameter of an upper surface, a bowing profile in which a diameter at a predetermined height position between an upper surface and a bottom surface is increased, or the like, for example.

Each of the columnar portions HRp includes a pedestal PDp at a junction portion in the junction layer JL. The pedestal PDp has a diameter larger than the diameter of the upper surface of the columnar portion HRpa arranged in the stacked body LMa or the like.

Each of the columnar portions HRpa and HRpb and the pedestal PDp includes dummy layers MEd, CNd, and CRd that are arranged in this order from an outer periphery thereof. The dummy layer CNd may be arranged also in a bottom of the columnar portion HRpa. The dummy layer MEd is a layer in which dummy layers BKd, CTd, and TNd are stacked in this order from the outer periphery of each of the columnar portions HRpa and HRpb and the pedestals PDp.

The dummy layers BKd, CTd, and TNd included in the dummy layer MEd correspond to the block insulating layer BK, the charge storage layer CT, and the tunnel insulating layer TN of the pillar PL, respectively, for example. Those dummy layers BKd, CTd, and TNd, like the above-mentioned layers in the pillar PL, are mainly made of SiI₂/SiN/SiO₂ or the like as a second material, for example.

The dummy layer CRd corresponds to the core layer CR of the pillar PL, and the dummy layer CRd, like the core layer CR, is mainly made of SiO₂ or the like, for example.

The dummy layer CNd corresponds to the channel layer CN of the pillar PL, and the dummy layer CNd, like the channel layer CN, is mainly made of at least one of amorphous silicon as a first material, polysilicon as a first material, and the like, for example. In other words, the dummy layer CNd may be any of an amorphous silicon layer, a polysilicon layer, and a layer of mixture of those materials, for example.

The dummy layer CNd produces a stronger ultraviolet-light blocking effect than an ultraviolet-light blocking effect produced by the insulating layer filled in the columnar portion HR, for example. More specifically, amorphous silicon, polysilicon, and the like, for example, that mainly make up the dummy layer CNd have a property of absorbing ultraviolet light, and thus have a higher ultraviolet-light blocking capability than that of the insulating layer filled in the columnar portion HR, for example. This allows the dummy layer CNd to produce an ultraviolet-light blocking effect.

In the present specification, the term “blocking” means attenuation of ultraviolet light to a predetermined light amount, in addition to complete blocking of ultraviolet light. Further, in the present specification, the term “ultraviolet light” means light of wavelengths from 100 nm or more to 400 nm or less, for example, in a broad sense, while meaning light of wavelengths from 200 nm or more to 300 nm or less, i.e., deep ultraviolet (DUV) light, for example, in a narrow sense.

The columnar portions HR and HRp support a stacked structure included in the semiconductor memory device 1 being manufactured, between two contacts LI arranged on both sides of the plate-shaped portion BR during later-described manufacturing processes of the semiconductor memory device 1.

Next, details of a configuration of the staircase region SR will be described.

As described above, the staircase region SR includes a stepped portion that is adjacent to the memory region MR in the X direction and ascends toward the memory region MR. Thus, the staircase region SR has a sectional structure that differs depending on a position in the X direction. In a position farthest from the memory region MR, the word line WL and the insulating layer OL in the lowermost layer of the stacked body LMa are arranged on the source line SL. As a position is nearer to the memory region MR, more layers are included in the stacked body LMa on the source line SL. Further, the respective layers of the stacked body LMb are arranged with the junction layer JL interposed. Then, in a position closest to the memory region MR, all layers in the stacked body LMb, including the word line WL and the insulating layer OL in the uppermost layer, are arranged.

FIGS. 2C and 3C illustrate the third step from the bottom in the stepped portion. The third step includes three sets of the word line WL and the insulating layer OL, except the lowermost insulating layer OL. Further, on one of sides in the Y direction in FIG. 2C, there is illustrated a section of the stepped portion, taken along the Y direction, in the staircase region SR that is formed in a shape of a mortar on both sides in the X direction and one of sides in the Y direction. In an upper layer of this configuration, the insulating layer 51 is arranged. Thus, the steps of the staircase region SR are covered with the insulating layer 51 so that the staircase region SR is at substantially the same height as an upper surface of the stacked body LMb in the memory region MR. The insulating layer 53 is arranged on the insulating layer 51, and the insulating layer 54 is arranged on the insulating layer 53.

The third word line WL from the bottom, which corresponds to the uppermost layer in the third step, is connected to the contact CC penetrating the insulating layer OL on the word line WL and the insulating layers 51 and 53. The contact CC is connected to an upper-layer wiring via the plug V0 penetrating the insulating layer 54. In this manner, in the staircase region SR, the word lines WL connected to the memory cells MC arranged in a height direction, respectively, are led in step-shapes and are connected to the contacts CC arranged in the respective steps of the staircase region SR.

Around the contact CC, the plurality of columnar portions HR penetrating the insulating layer 51 and the stacked bodies LMa and LMb is arranged in a matrix. In the position illustrated in FIG. 2C, each of the columnar portions HR extends from a lower portion of the insulating layer 53, penetrates the third step of the stepped portion in the stacked body LMa, and reaches the source line SL.

The columnar portion HR arranged in the staircase region SR includes the columnar portion HRa, the columnar portion HRb, and the pedestal PDr each of which is filled with an insulating layer as an insulating material such as a SiO₂ layer, and has a configuration, a shape, and the like that are similar to a configuration, the shape, and the like of the columnar portion HR arranged near the through contact region TP.

(Manufacturing Method of Semiconductor Memory Device)

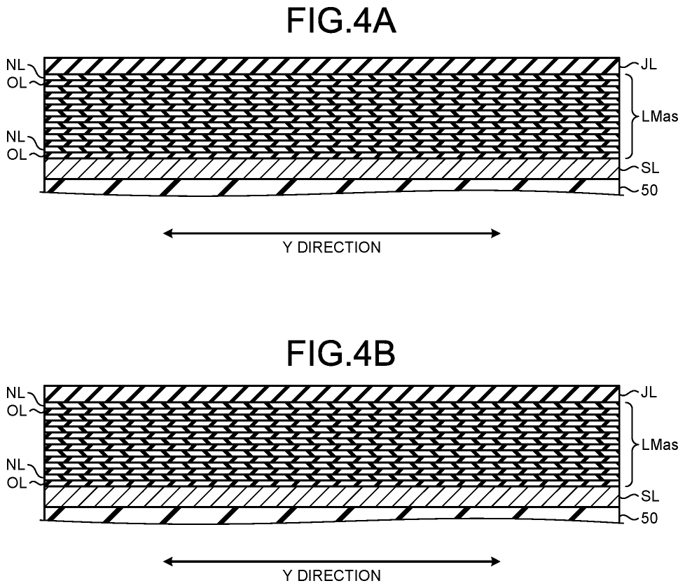

Next, an example of a manufacturing method of the semiconductor memory device 1 of the first embodiment will be described with reference to FIGS. 4A to 23C.

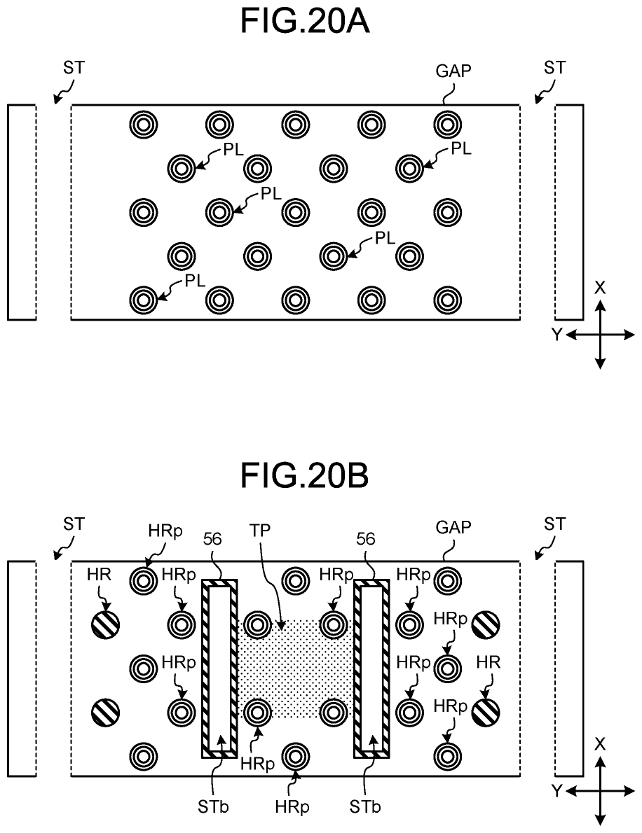

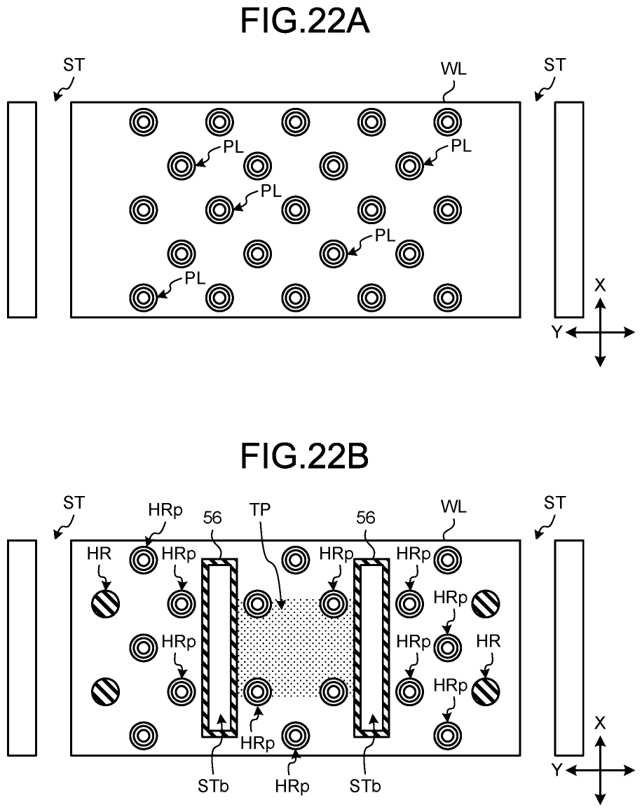

FIGS. 4A to 19B and FIGS. 21A and 21B are sectional views illustrating an example of a procedure for the manufacturing method of the semiconductor memory device 1 according to the first embodiment. FIGS. 20A and 20B and FIGS. 22A and 22B are cross-sectional views illustrating the example of the procedure for the manufacturing method of the semiconductor memory device 1 according to the first embodiment.

In FIGS. 4A to 22B, the figures having the same figure number and different alphabets “A” and “B” illustrate different sectional views in the same process. In FIGS. 4A to 19B and FIGS. 21A and 21B, the figures with “A” illustrate sections of a portion illustrated in FIG. 2A, and the figures with “B” illustrate sections of a portion illustrated in FIG. 2B. In FIGS. 20A and 20B and FIGS. 22A and 22B, the figures with “A” illustrate sections of a portion illustrated in FIG. 3A and the figures with “B” illustrate sections of a portion illustrated in FIG. 3B.

Below, description will be started from a status of a process to be performed after the peripheral circuit CUA including the transistor TR is formed on the substrate SB and the peripheral circuit CUA is covered with the insulating layer 50.

As illustrated in FIGS. 4A and 4B, the source line SL is formed on the insulating layer 50 and a stacked body LMas in which the insulating layers NL and the insulating layers OL are alternately stacked is formed on the source line SL. The insulating layer NL as sacrificial layer is SiN layer or the like, for example, and is replaced with a conductive material at a later time, to serve as the word line WL. The junction layer JL is formed on the stacked body LMas.

Meanwhile, at that time, in the staircase region (not illustrated), a lower stepped portion formed of the stacked body LMas out of the whole structure of the stepped portion is formed. On the steps of the lower stepped portion, the insulating layer 51 is formed to the same height as the height of an upper surface of the junction layer JL, for example.

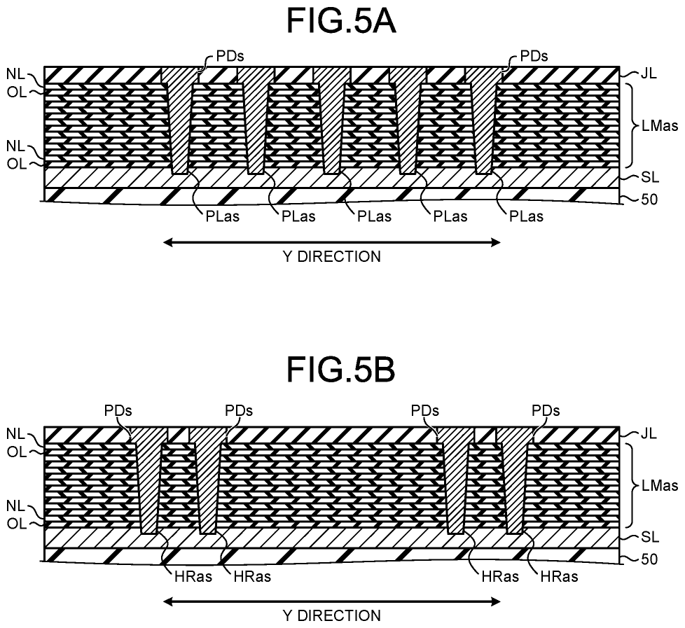

As illustrated in FIG. 5A, a memory hole that penetrates the junction layer JL and the stacked body LMas to reach the source line SL and has an increased diameter in its upper end is formed in the stacked body LMas. The memory hole is filled with a sacrificial layer such as an amorphous silicon layer. This results in formation of a pillar PLas that includes a pedestal PDs in a portion with an increased diameter in the upper end of the memory hole.

As illustrated in FIG. 5B, in parallel with formation of the pillar PLas, a hole that penetrates the junction layer JL and the stacked body LMas to reach the source line SL and has an increased diameter in its upper end is formed in the stacked body LMas. The hole is filled with a sacrificial layer such as an amorphous silicon layer. This results in formation of a columnar portion HRas that includes a pedestal PDs in a portion with an increased diameter in the upper end of the hole. At that time, the columnar portion HRas is formed also in the staircase region not illustrated, in a similar manner.

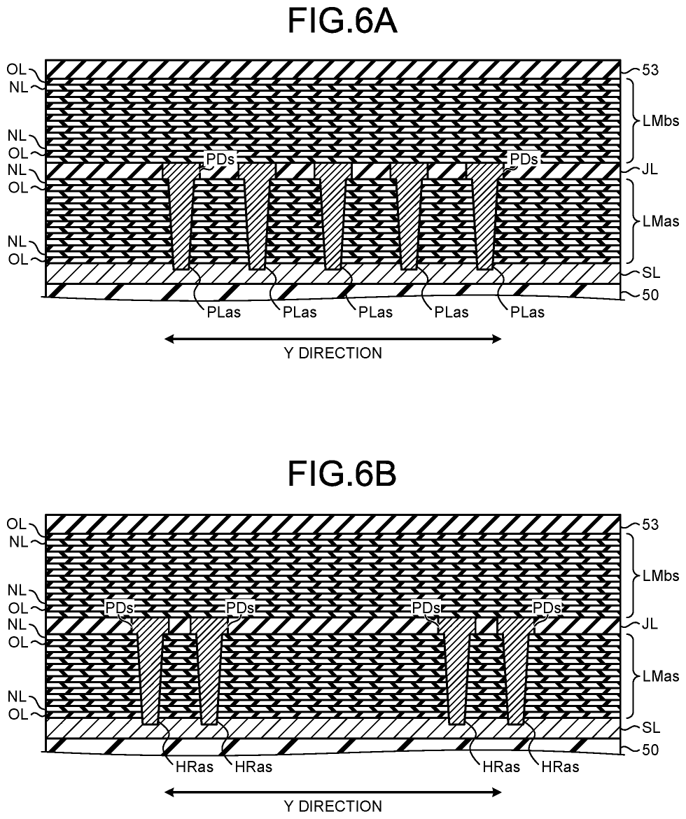

As illustrated in FIGS. 6A and 6B, the stacked body LMbs in which the insulating layers NL and the insulating layers OL are alternately stacked is formed on the upper layers of the above-described respective portions. That is, in portions illustrated in FIGS. 6A and 6B, the stacked body LMbs is formed on the stacked body LMas with the junction layer JL interposed.

Further, in the staircase region not illustrated, the stacked body LMbs is processed and the whole of the staircase region including the stepped portion formed in the stacked body LMas is formed. On the steps of the staircase region, the insulating layer 51 is formed to the same height as the height of an upper surface of the stacked body LMbs, for example.

Thereafter, the insulating layer 53 covering the respective portions illustrated in FIGS. 6A and 6B and the staircase region (not illustrated) is formed. In other words, the insulating layer 53 is formed on the stacked body LMbs in the portions illustrated in FIGS. 6A and 6B. In the staircase region (not illustrated), the insulating layer 53 is formed on the insulating layer 51.

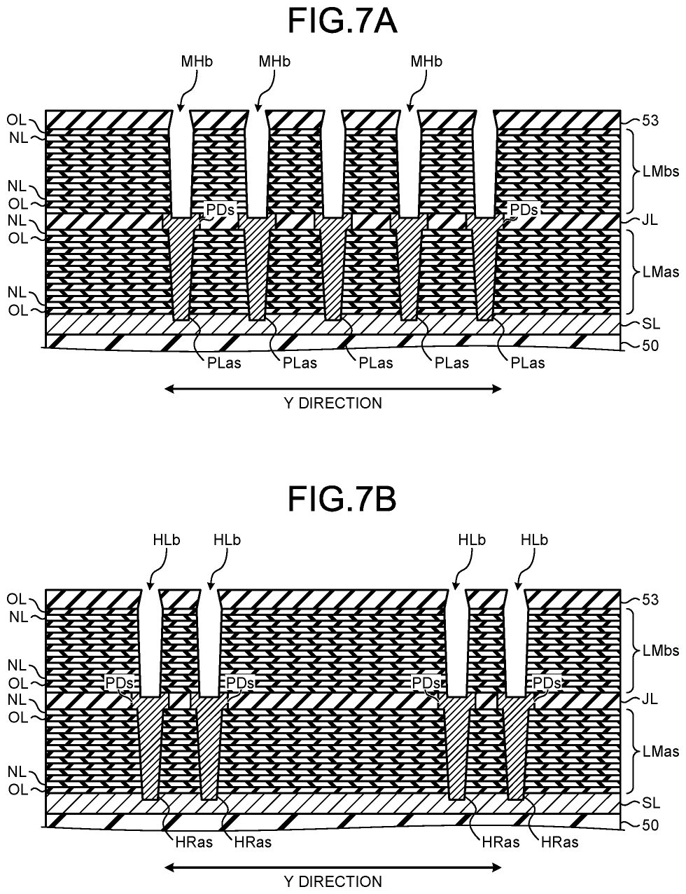

As illustrated in FIG. 7A, memory holes MHb that penetrate the insulating layer 53 and the stacked body LMbs and are connected to the respective pedestals PDs in the junction layer JL are formed.

In an upper surface of the pillar PLas, the pedestal PDs having a diameter larger than a diameter of the pillar PLas in the stacked body LMas is arranged. This allows the memory hole MHb and the pillar PLas to be connected to each other via the pedestal PDs even if occurring an incomplete coincidence of vertical arrangement positions of the pillar PLas and the memory hole MHb due to misalignment or the like, in forming the memory hole MHb in the stacked body LMbs.

As illustrated in FIG. 7B, in parallel with formation of the memory holes MHb, holes HLb that penetrate the insulating layer 53 and the stacked bodies LMb and are connected to the respective pedestals PDs of the columnar portions HRas are formed. At that time, the holes HLb are formed also in the staircase region not illustrated, in a similar manner.

In an upper surface of the columnar portion HRas, the pedestal PDs having a diameter larger than a diameter of the columnar portion HRas in the stacked body LMas is arranged. This allows the hole HLb and the columnar portion HRas to be connected to each other via the pedestal PDs even if occurring an incomplete coincidence of vertical arrangement positions of the columnar portion HRas and the hole HLb due to misalignment or the like, in forming the hole HLb in the stacked body LMbs.

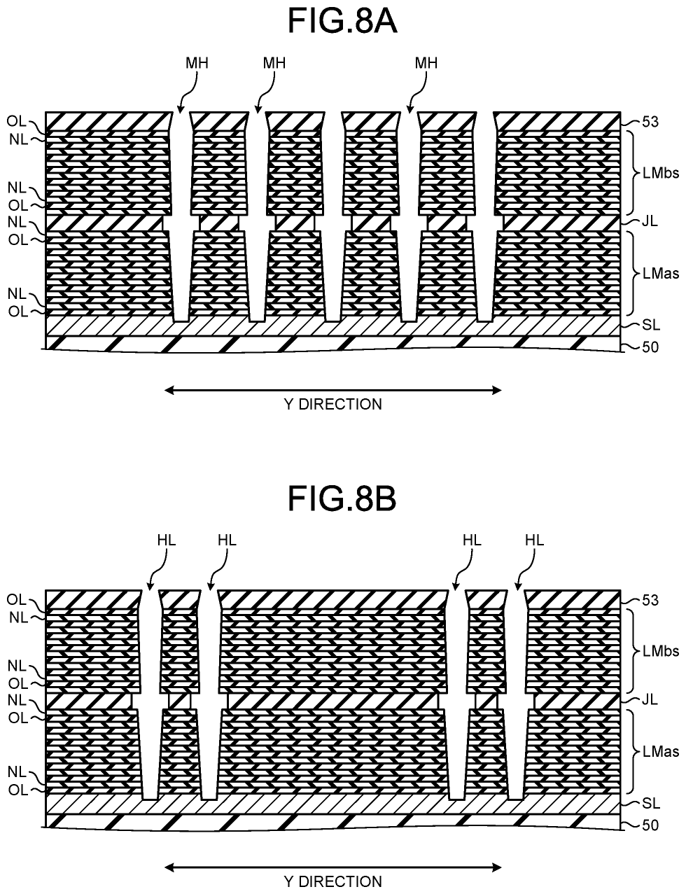

As illustrated in FIG. 8A, the sacrificial layers in the pillars PLas are removed through the memory holes MHb, and the memory holes MH that penetrate the stacked body LMbs, the junction layer JL, and the stacked body LMas and reach the source line SL are formed.

As illustrated in FIG. 8B, in parallel with removal of the sacrificial layers in the pillars PLas, the sacrificial layers in the columnar portions HRas are removed through the holes HLb, and thus the holes HL that penetrate the stacked body LMbs, the junction layer JL, and the stacked body LMas and reach the source line SL are formed. At that time, the holes HL are formed also in the staircase region not illustrated, in a similar manner.

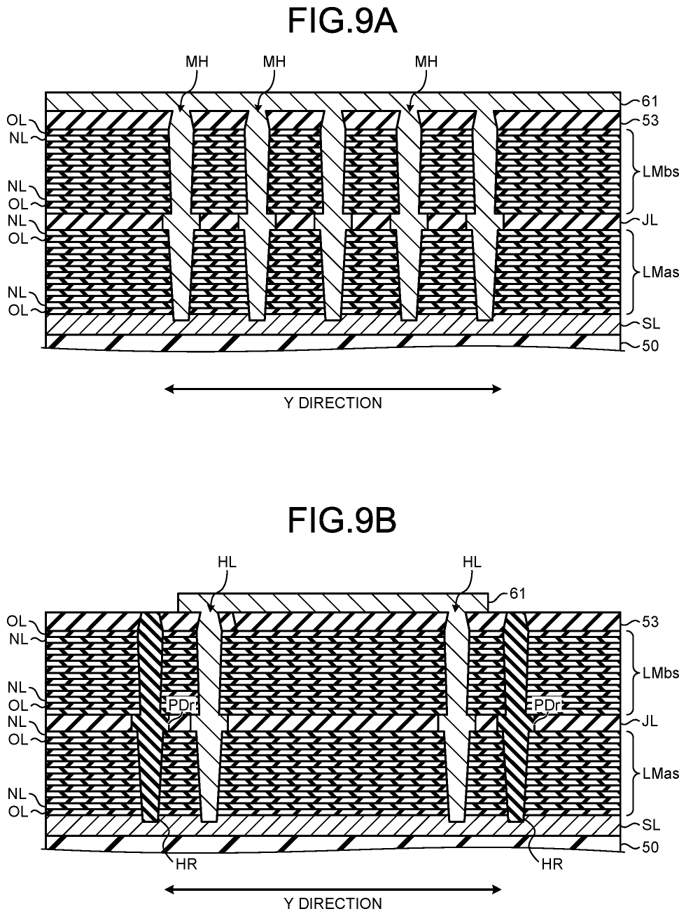

As illustrated in FIGS. 9A and 9B, the memory holes MH and a part of the holes HL are covered with a mask film 61 or the like.

Referring to FIG. 9B, the part of the holes HL covered with the mask film 61 corresponds to the holes HL that serve as the columnar portions HRp at a later time. In other words, in the portion illustrated in FIG. 9B, the holes HL except the hole HL arranged in a position where the hole is adjacent to the contact LI at a later time, for example, are covered with the mask film 61.

As illustrated in FIG. 9B, each of the holes HL that are not covered with the mask film 61 is filled with an insulating layer, thereby forming the columnar portions HR each including the pedestal PDr at its center. At that time, the columnar portions HR are formed also in the staircase region not illustrated, in a similar manner.

Thereafter, the mask film 61 is removed.

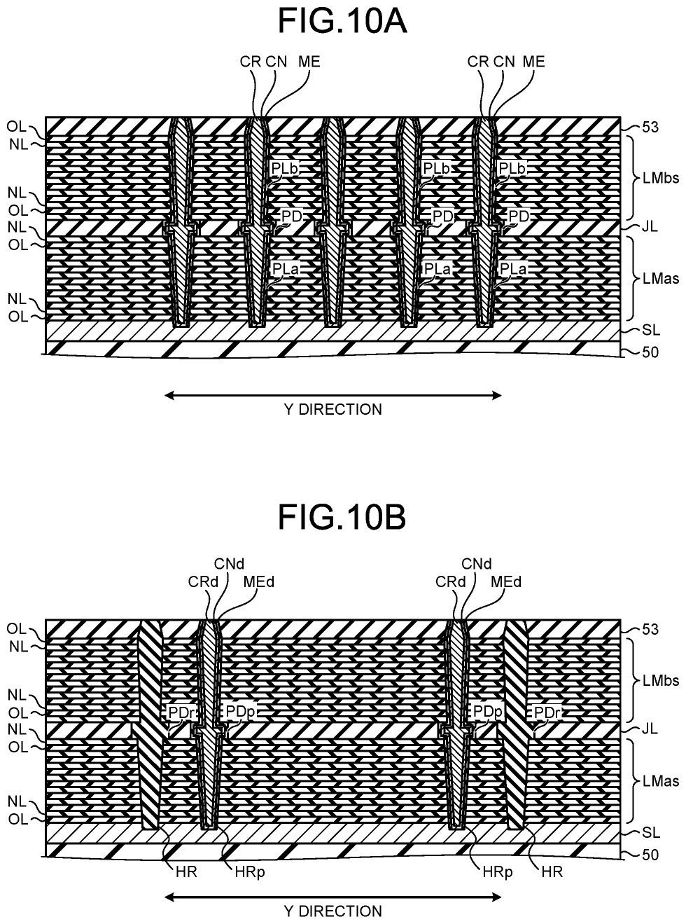

As illustrated in FIG. 10A, the pillars PLa and PLb are formed in the stacked bodies LMas and LMbs. Specifically, the memory layer ME such as SiO₂ layer/SiN layer/SiO₂ layer, the channel layer CN such as an amorphous silicon layer or a polysilicon layer, and the core layer CR such as a SiO₂ layer are formed sequentially in this order from an outer periphery of the memory hole MH. The channel layer CN is formed also in a bottom of the memory hole MH. This results in formation of the pillars PLa and PLb each including the pedestal PD at its center.

As illustrated in FIG. 10B, in parallel with formation of the pillars PLa and PLb, the columnar portions HRp are formed in the stacked bodies LMas and LMbs or the like. Specifically, the dummy layer MEd such as SiO₂ layer/SiN layer/SiO₂ layer, the dummy layer CNd such as an amorphous silicon layer or a polysilicon layer, and the dummy layer CRd such as a SiO₂ layer are formed sequentially in this order from an outer periphery of the hole HL left while being un-filled with an insulating layer. The dummy layer CNd may be formed also in a bottom of the hole HL. This results in formation of the columnar portions HRp each including the pedestal PDp at its center.

Additionally, the channel layers CN formed in the pillars PLa and PLb and the dummy layer CNd formed in the columnar portion HRp may be layers mainly made of amorphous silicon at an initial stage of these formation, for example. Then, in the semiconductor memory device 1 provided as a finished product, a part or the whole of the amorphous silicon included in the channel layers CN and the dummy layer CNd may be transformed into polysilicon by being subjected to degeneration due to heat treatment or the like included in various processes to be subsequently performed.

Here, the process illustrated in FIGS. 9A and 9B and the process illustrated in FIGS. 10A and 10B are interchangeable with each other.

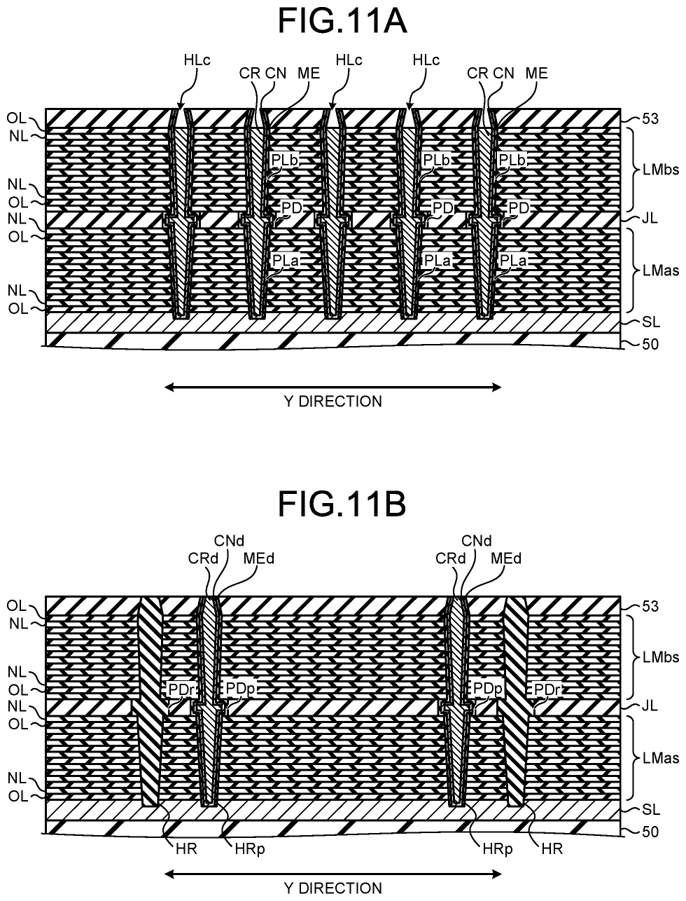

As illustrated in FIG. 11A, an upper end of the pillar PLb, or at least an upper end of the core layer CR, exposed in an upper surface of the insulating layer 53, is etched back, and a hole HLc is formed in the upper end of the pillar PLb. At that time, upper ends of the columnar portions HR and HRp in the portion illustrated in FIG. 11B, as well as upper ends of the columnar portions HR in the staircase region not illustrated, are prevented from being etched back.

For example, the memory layer ME, the channel layer CN, and the core layer CR filled in the memory hole MH during formation of the pillars PLa and PLb are formed also on the insulating layer 53 where upper surfaces of the columnar portions HR are exposed. Thus, by selective etch-back of only the core layer CR, for example, an upper surface of the insulating layer 53 is protected by the channel layer CN serving as an etch stopper layer and the core layer CR of the pillar PLb exposed in the upper surface of the insulating layer 53 is removed.

Meanwhile, in the columnar portion HR, also an upper surface of the columnar portion HR is covered with the channel layer CN or the like, and thus, an upper end of the columnar portion HR is prevented from being removed. The columnar portion HRp having its upper end exposed in an upper surface of the insulating layer 53, like the pillar PLb, may be covered with a mask material or the like in an additional process.

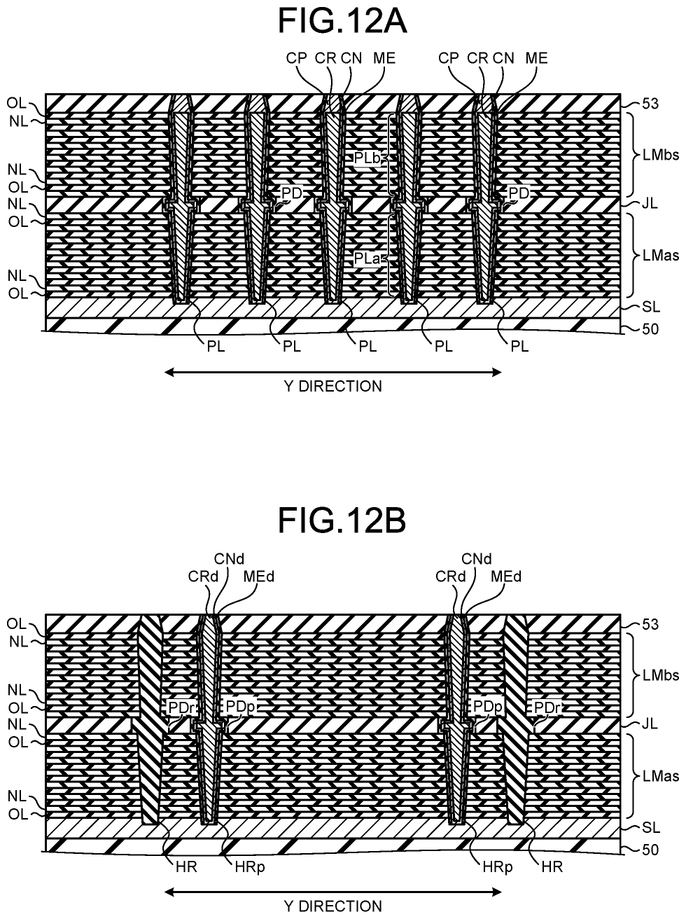

As illustrated in FIG. 12A, the hole HLc surrounded by the memory layer ME and the channel layer CN in an upper end of the pillar PLb is filled with an amorphous silicon layer, a polysilicon layer, or the like, thereby forming the cap layer CP having a diameter approximately equal to at least an outer diameter of the core layer CR. The channel layer CN surrounding the cap layer CP and the cap layer CP may be substantially integral with each other so that the cap layer CP can seem to have a diameter approximately equal to an outer diameter of the channel layer CN. This results in formation of the pillar PL having the cap layer CP in its upper end.

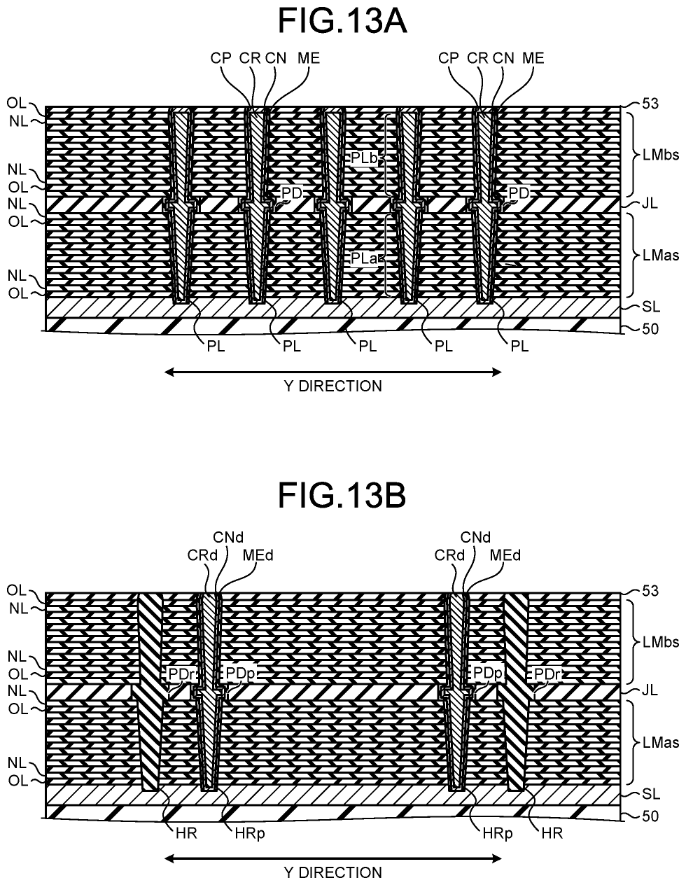

As illustrated in FIGS. 13A and 13B, the entire surface of the insulating layer 53 is etched back and thus the insulating layer 53 is made thinner. At that time, as illustrated in FIG. 13A, also an upper portion of the cap layer CP in an upper end of the pillar PL is etched back. Further, as illustrated in FIG. 13B, upper portions of the columnar portions HR and HRp are etched back. Moreover, an upper portion of the columnar portion HR in the staircase region not illustrated is etched back in a similar manner.

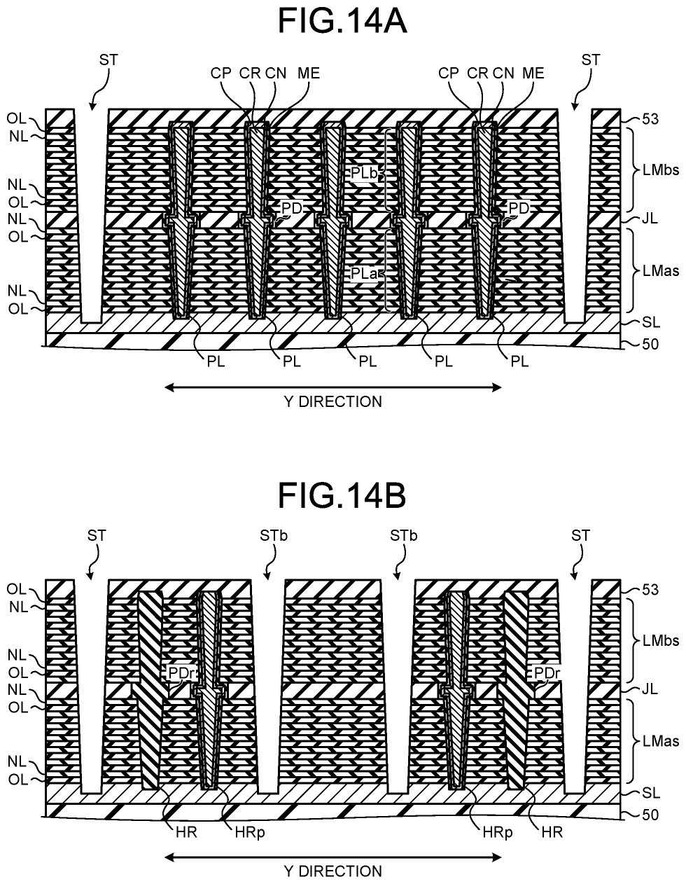

As illustrated in FIGS. 14A and 14B, the insulating layer 53 is formed thicker again, and thus the respective portions illustrated in FIGS. 14A and 14B and the whole of the staircase region not illustrated are covered with the insulating layer 53. As a result of this, the cap layer CP of the pillar PL is arranged in a lower portion of the insulating layer 53 and the upper ends of the columnar portions HR and HRp are arranged in the lower portion of the insulating layer 53.

As illustrated in FIGS. 14A and 14B, slits ST that penetrate the insulating layer 53, the stacked body LMbs, the junction layer JL, and the stacked body LMas and reach the source line SL are formed. The slits ST are each formed so as to extend in the X direction over a region corresponding to the memory region MR in FIG. 14A, the vicinity of a region where the through contact region TP is to be formed in FIG. 14B, and a region corresponding to the staircase region (not illustrated).

As illustrated in FIG. 14B, in parallel with formation of the slits ST, slits STb that penetrate the insulating layer 53, the stacked body LMbs, the junction layer JL, and the stacked body LMas and reach the source line SL are formed. The slits STb are formed locally in the vicinity of a region where the through contact region TP is to be formed.

The slits ST are then used for replacing the insulating layers NL with the word lines WL at a later time, and thereafter serve as the contacts LI that divide the stacked bodies LMas and LMbs. The slits STb are then used for forming the through contact region TP, and thereafter serve as the plate-shaped portions BR arranged in the vicinity of the through contact region TP.

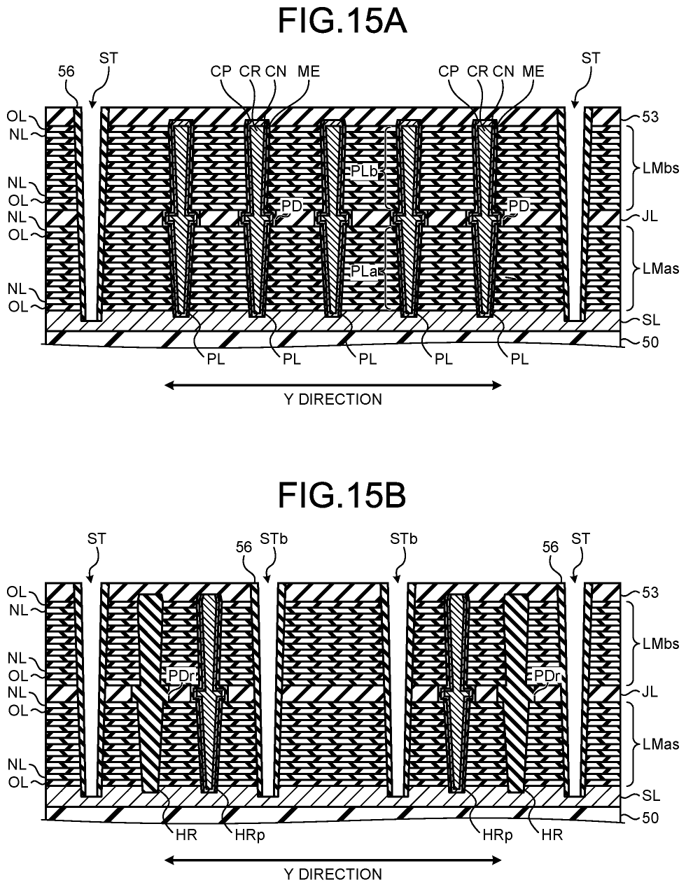

As illustrated in FIG. 15B, an insulating layer 56 such as a SiO₂ layer is formed on a sidewall of the slit STb so that the slit STb can be used for formation of the through contact region TP.

At that time, as illustrated in FIGS. 15A and 15B, the insulating layer 56 is formed also on a sidewall of the slit ST. However, as the slit ST is used for replacing the insulating layers NL with the word lines WL, the insulating layer 56 on a sidewall of the slit ST is removed in the following manner.

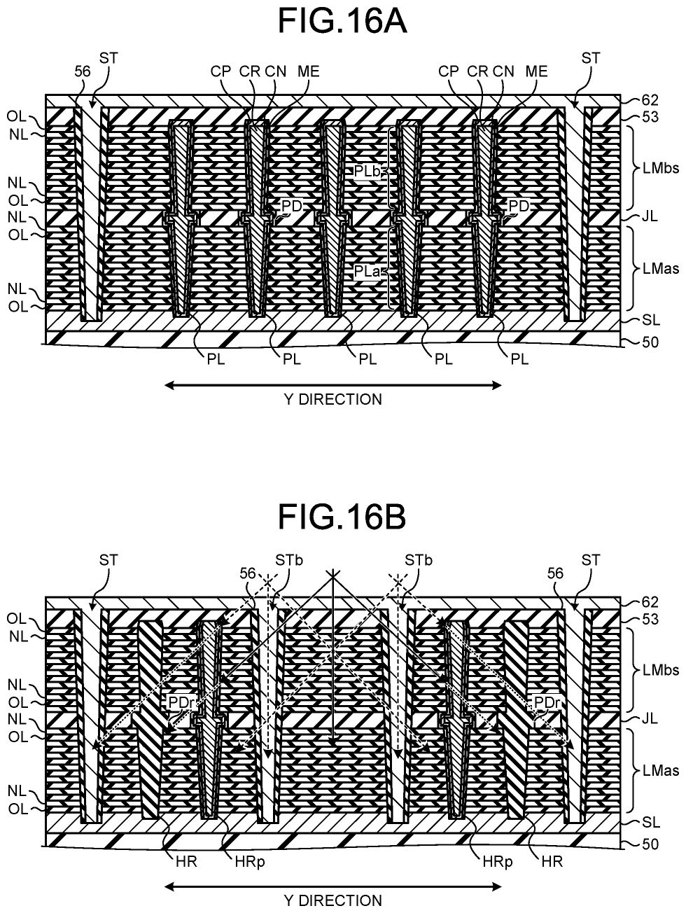

As illustrated in FIGS. 16A and 16B, a negative resist film 62 covering all of the respective portions is formed. The negative resist film 62 covers the upper surfaces of the respective portions, and further is filled in the slits ST and STb. In a case of the negative resist film 62, a portion other than a portion exposed to ultraviolet light such as DUV light is removed by development.

As illustrated in FIG. 16B, in order to leave the negative resist film 62 in the slits STb, ultraviolet light such as DUV light is applied from above the slits STb, and the negative resist film 62 in and on the slits STb are exposed to the light.

At that time, diffraction, interference, and the like of ultraviolet light applied to the slits STb occur at the slits STb and structures or the like around the slits STb, in some cases. For this reason, ultraviolet light proceeds toward the slits ST, for example, so that also the negative resist film 62 filled in the slits ST may be exposed to light. Such a phenomenon in which the negative resist film 62 in a region not intended for exposure is exposed to light is called spurious resolution.

However, the columnar portion HRp arranged adjacently to the slit STb includes the dummy layer CNd that produces a strong ultraviolet light absorbing effect. Thus, ultraviolet light directed toward the slit ST, for example, is blocked by the columnar portion HRp, so that occurrence of spurious resolution in the negative resist film 62 filled in the slit ST is suppressed.

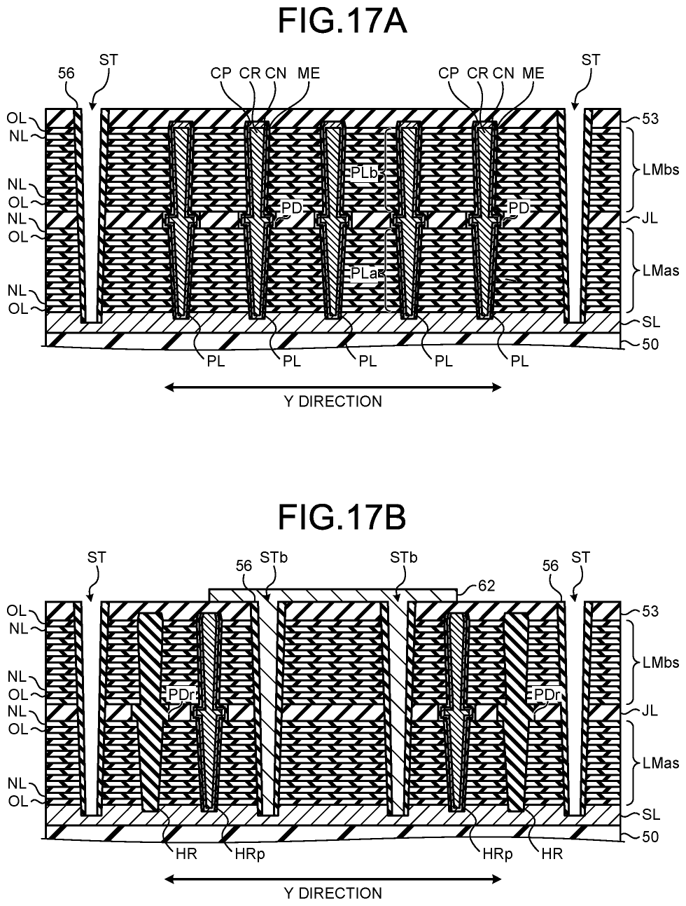

As illustrated in FIGS. 17A and 17B, when the negative resist film 62 covering all of the respective portions is developed, the negative resist film 62 is left in and on the slits STb, and the other portion of the negative resist film 62 including the negative resist film 62 in the slits ST is removed.

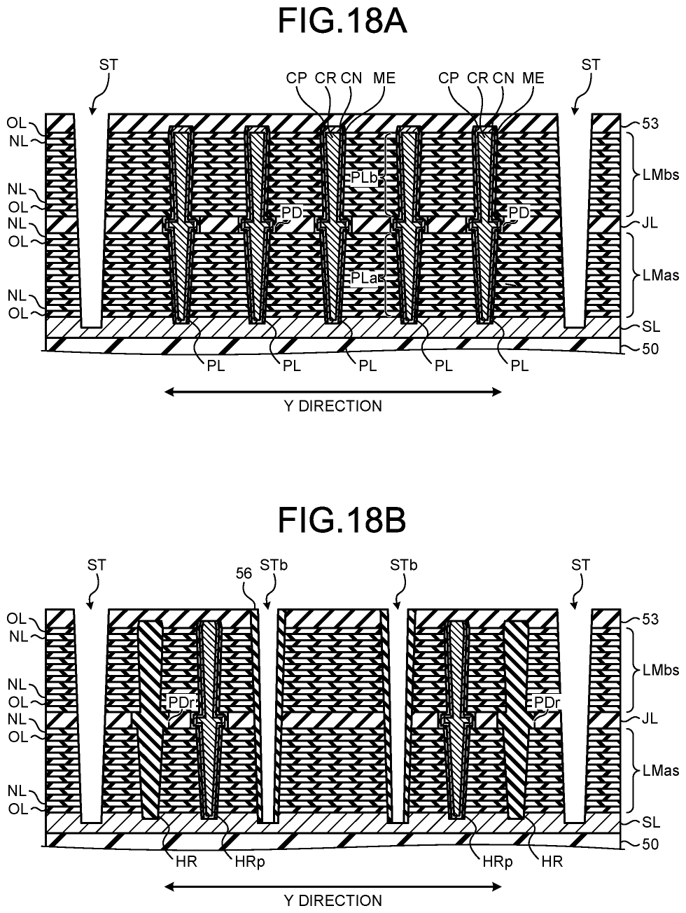

As illustrated in FIGS. 18A and 18B, after the negative resist film 62 is developed and exposed portions of the insulating layer 56 in the slits ST are removed, the negative resist film 62 covering the slits STb is removed. As a result of this, ends of the stacked bodies LMas and LMbs are exposed in sidewalls of the slits ST while the sidewalls of the slits STb remain covered with the insulating layer 56.

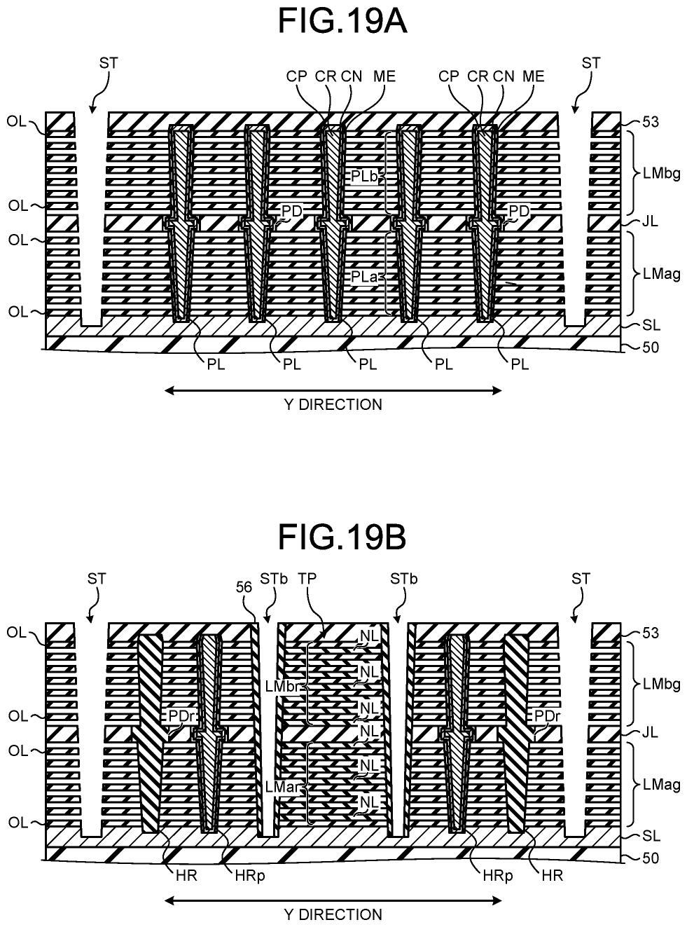

As illustrated in FIGS. 19A and 19B and FIGS. 20A and 20B, the insulating layers NL in the stacked bodies LMas and LMbs are removed through the slits ST penetrating the stacked bodies LMas and LMbs. This results in formation of stacked bodies LMag and LMbg in which gaps are formed between the insulating layers OL.

At that time, as illustrated in FIGS. 19B and 20B, in the regions illustrated therein, the slits STb including the insulating layers 56 on the sidewalls thereof prevent a chemical solution or the like that is used for removing the insulating layers NL and flows from the slits ST, from flowing into a region sandwiched between the slits STb. Then, the process is stopped before the chemical solution or the like makes a detour through ends of the slits STb (from the X direction) and flows into the above-described region far from the ends of the slits STb. Thus, the insulating layers NL are left without being removed in the region between two slits STb.

As a result of this, the through contact region TP including the stacked bodies LMar and LMbr is formed in an approximate center of the region between the slits STb illustrated in FIGS. 19B and 20B.

Further, at that time, the stacked bodies LMag and LMbg that are fragile structures because of inclusion of the gaps are supported by the pillars PL in the position illustrated in FIG. 19A, supported by the columnar portions HR and HRp in the position illustrated in FIG. 19B, and supported by the columnar portions HR in the staircase region not illustrated.

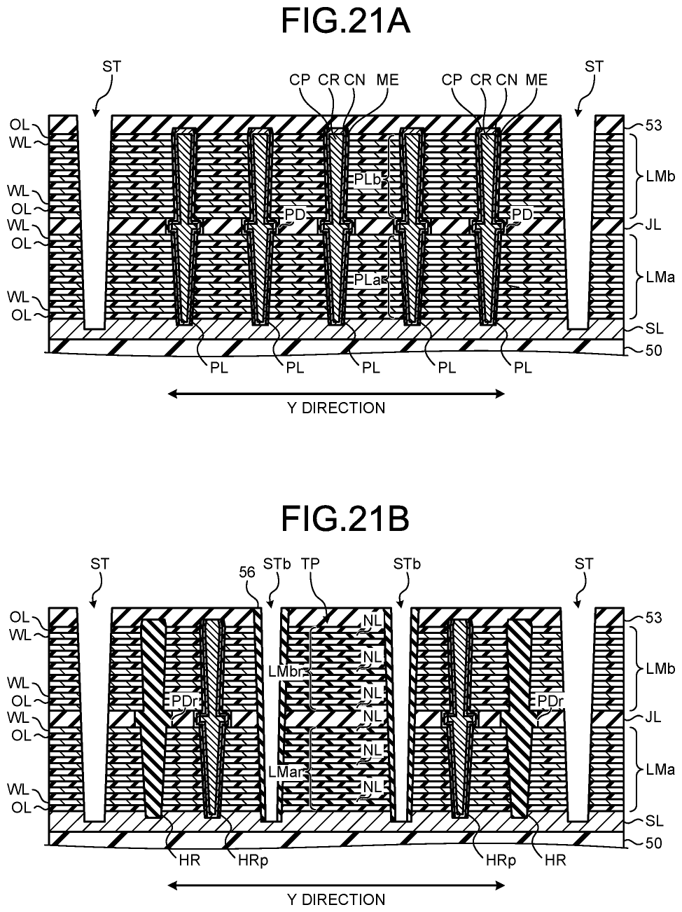

As illustrated in FIGS. 21A and 21B and FIGS. 22A and 22B, the gaps in the stacked bodies LMag and LMbg are filled with a conductive material such as tungsten or molybdenum through the slits ST penetrating the stacked bodies LMag and LMbg. This results in formation of the stacked bodies LMa and LMb in which the word lines WL are formed between the insulating layers OL.

Also at that time, as illustrated in FIGS. 21B and 22B, the slits STb prevent a gas for depositing a conductive layer such as a tungsten layer from flowing into the through contact region TP. This keeps the states of the stacked bodies LMar and LMbr including the insulating layers NL in the through contact region TP, unchanged.

A process of replacing the insulating layers NL with the word lines WL in the manner illustrated in FIGS. 19A to 22B is sometimes called replacement.

Thereafter, the above-described insulating member (not illustrated) is formed in the stacked body LMb. For formation of the insulating member, a trench that halfway penetrates the stacked body LMb (the conductive layer and the insulating layer thereon further above the stacked body LMb), for example, is formed, and the trench is filled with an insulating layer. Additionally, the trench used for forming the insulating member may be formed in parallel with formation of the above-described slits ST and STb, and the trench may be filled with an insulating layer, thereby forming the insulating member before the processes related to the slits ST and STb.

Further, the slit STb is filled with an insulating layer, thereby forming the plate-shaped portion BR. Moreover, the insulating layer 52 is formed on a sidewall of the slit ST and the inner side of the sidewall is filled with the conductive layer 20, thereby forming the contact LI.

Further, the contact CC that penetrates the insulating layers 53 and 51 and reaches the word line WL in the uppermost layer in the steps of the staircase region SR is formed. Moreover, the contact C4 that penetrates the insulating layer 53, the stacked bodies LMar and LMbr, and the source line SL and is electrically connected to the transistor TR or the like of the peripheral circuit CUA is formed.

Further, after the insulating layer 54 covering the insulating layer 53 is formed, the plug CH that penetrates the insulating layers 54 and 53 and is connected to the cap layer CP of the pillar PL, and the plug V0 that penetrates the insulating layer 54 and is connected to the contacts LI, CC, and C4 are formed. Moreover, an upper-layer wiring or the like connected to those plugs CH and V0 is formed.

By the above-described processes, the semiconductor memory device 1 of the first embodiment is manufactured.

In manufacturing processes of a semiconductor memory device such as a three-dimensional nonvolatile memory, in some cases, an insulating layer is left in a partial region of a stacked body in order to pass a contact that connects a peripheral circuit arranged on a substrate and an upper-layer wiring or the like arranged above the stacked body, for example. In such cases, a slit having a sidewall covered with an insulating layer is formed in the vicinity of the partial region, to inhibit replacement in the partial region of the stacked body and leave the insulating layer in the partial region.

Such a slit for inhibiting replacement is occasionally formed in parallel with formation of a slit for replacement, for example. In this case, an insulating layer is removed from a sidewall of the slit for replacement while the inside of the slit for inhibiting replacement is kept protected with a negative resist film or the like.

Those two kinds of slits, however, are formed closely to each other in a relatively small region. For this reason, when the negative resist film in the slit for inhibiting replacement is exposed to light, also a negative resist film in the slit for replacement is exposed to light due to spurious resolution, in some cases. In such cases, a part of the negative resist film is left also in the slit for replacement, so that a part of the insulating layer on the sidewall of the slit is left unremoved. This inhibits replacement with a word line in a portion of the stacked body in the vicinity of the unremoved insulating layer, in some cases.

According to the semiconductor memory device 1 of the first embodiment, the columnar portion HRp extends in the stacking direction of the stacked bodies LMa and LMb in a position adjacent to the plate-shaped portion BR and includes at least one of amorphous silicon and polysilicon that produces a stronger ultraviolet-light blocking effect than an ultraviolet-light blocking effect produced by an insulating layer filled in the columnar portion HR.

Thus, ultraviolet light directed to the slit ST can be absorbed or attenuated, which suppresses occurrence of spurious resolution in the negative resist film 62 in the slit ST. Therefore, it is possible to replace the insulating layers NL more surely in the other regions with the word lines WL, while leaving the insulating layers NL in a partial region of the stacked bodies LMas and LMbs.

According to the semiconductor memory device 1 of the first embodiment, the columnar portion HRp extends in the stacking direction of the stacked bodies LMa and LMb and includes the dummy layer CNd including at least one of amorphous silicon and polysilicon.

This enhances an ultraviolet-light blocking effect produced by the columnar portion HRp over the whole of the stacked bodies LMa and LMb in the stacking direction, for example, thereby more surely suppressing occurrence of spurious resolution in the negative resist film 62 in the slit ST.

According to the semiconductor memory device 1 of the first embodiment, the columnar portion HR that extends through the stacked bodies LMa and LMb in the stacking direction in a position between the contacts LI arranged on both sides of the plate-shaped portion BR, and includes an insulating layer, is arranged adjacently to the contact LI.

In the plurality of columnar portions HR and HRp arranged closely to each other in a matrix between two contacts LI, one row closest to the contact LI may occasionally come into contact with the contact LI. As described above, at least the one row closest to the contact LI is formed so as to include the columnar portions HR each filled with an insulating layer. Thus, even if the contact LI and the columnar portions HR come into contact with each other, electrical influences on operations of the semiconductor memory device 1 can be suppressed.

Note that, in the above-described first embodiment, the columnar portion HR is arranged adjacently to the contact LI, for example. However, as far as the columnar portion HRp is arranged adjacently to the plate-shaped portion BR, for example, the above-described effect of suppressing spurious resolution of the negative resist film 62 in the slit ST can be attained. Thus, the columnar portion HR may be arranged in the other regions except one row adjacent to the plate-shaped portion BR.

In other words, a plurality of rows in the Y direction in a region between the plate-shaped portion BR and the contact LI, except one row closest to the plate-shaped portion BR, may each include the columnar portions HR. Further, the columnar portion HR may be arranged in a region sandwiched between two plate-shaped portions BR.

However, in a case where the columnar portion HR is arranged in a region sandwiched between two plate-shaped portions BR, for example, zoning for arranging the above-described mask film 61 illustrated in FIG. 9B is desired to be performed more finely. In this sense, it is preferable that the columnar portions HRp are consistently arranged in a region sandwiched between two plate-shaped portions BR and in a row adjacent to an outer one of the two plate-shaped portions BR.

### Second Embodiment

Below, a second embodiment will be described in detail with reference to the drawings. In the second embodiment, a configuration of a columnar portion that produces an ultraviolet-light blocking effect is different from the configuration of the columnar portion in the first embodiment.

(Configuration Example of Semiconductor Memory Device)

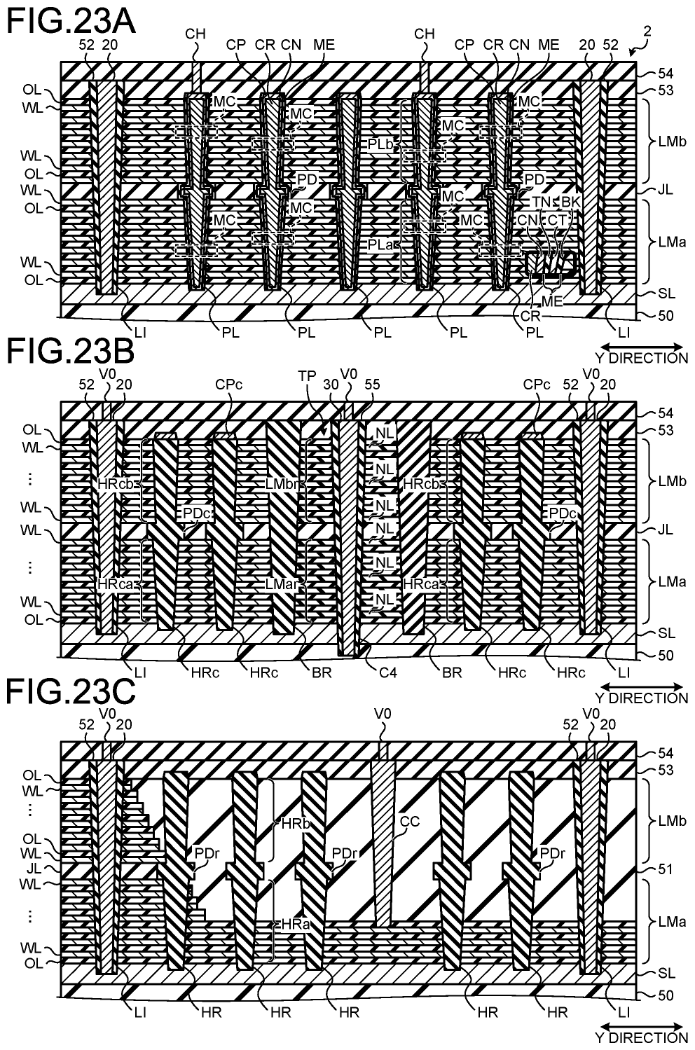

FIGS. 23A to 23C are sectional views of a semiconductor memory device 2 according to the second embodiment, taken along the Y direction. FIG. 23A is a sectional view of a memory region MR, FIG. 23B is a sectional view of a portion in the vicinity of a through contact region TP, and FIG. 23C is a sectional view of a staircase region SR.

Note that also the semiconductor memory device 2 of the second embodiment includes a peripheral circuit CUA arranged on a substrate SB and an upper-layer wiring or the like arranged above stacked bodies LMa and LMb. However, in FIGS. 23A to 23C, structures below the insulating layer 50, such as the substrate SB and the peripheral circuit CUA, and the upper-layer wiring or the like, are omitted.

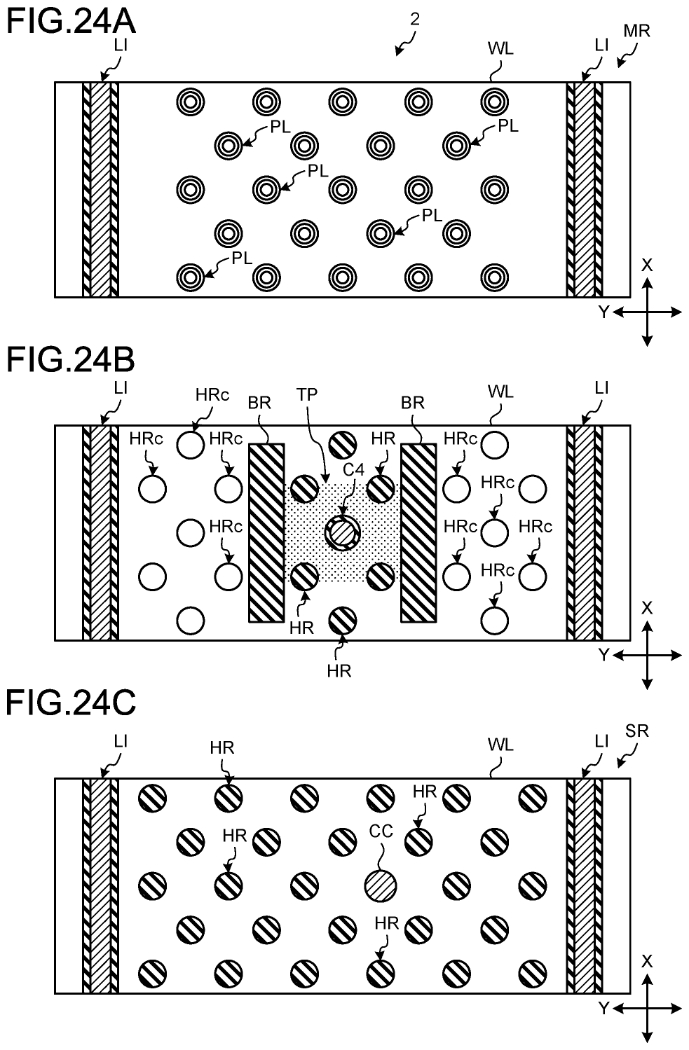

FIGS. 24A to 24C are cross-sectional views of the semiconductor memory device 2 according to the second embodiment. More specifically, FIGS. 24A to 24C are sectional views taken transversely at the height position of a word line WL connected to a contact CC in a position illustrated in FIG. 23C in the staircase region SR, among a plurality of word lines WL included in the semiconductor memory device 2. FIG. 24A is a cross-sectional view of the memory region MR, FIG. 24B is a cross-sectional view of a portion in the vicinity of the through contact region TP, and FIG. 24C is a cross-sectional view of the staircase region SR.

As illustrated in FIGS. 23A and 24A, the memory region MR of the semiconductor memory device 2 has a configuration similar to the configuration of the memory region MR of the semiconductor memory device 1 of the above-described first embodiment.

As illustrated in FIGS. 23C and 24C, the staircase region SR of the semiconductor memory device 2 has a configuration similar to the configuration of the staircase region SR of the semiconductor memory device 1 of the above-described first embodiment.

As illustrated in FIGS. 23B and 24B, a plurality of columnar portions HR and HRc is arranged in a matrix in a region including the through contact region TP and the vicinity of the through contact region TP of the semiconductor memory device 2.

The columnar portion HR has a configuration similar to the configuration of the columnar portion HR of the semiconductor memory device 1 of the above-described first embodiment, and is arranged in a region sandwiched between two plate-shaped portions BR, for example. Specifically, the columnar portion HR includes a columnar portion HRa that penetrates the stacked body LMa, a columnar portion HRb that has an upper end protruding into an insulating layer 53 and penetrates the stacked body LMb, and a pedestal PDr (refer to FIG. 23C) that connects the columnar portion HRa and the columnar portion HRb, for example.

Additionally, the columnar portions HRa and HRb may penetrate boundaries between the stacked bodies LMa and LMb and the stacked bodies LMar and LMbr, respectively, or may penetrate the stacked bodies LMar and LMbr, respectively.

The columnar portion HRc as a third columnar portion is arranged in a region sandwiched between a contact LI and the plate-shaped portion BR. In this regard, it is preferable that, for example, all of arrays along the contact LI and the plate-shaped portion BR in the Y direction between the contact LI and the plate-shaped portion BR include the columnar portions HRc.

The columnar portion HRc extends from a lower portion of an insulating layer 53, penetrates the stacked bodies LMa and LMb and a junction layer JL in a stacking direction of the stacked bodies LMa and LMb, and reaches the source line SL.

More specifically, the columnar portion HRc has a shape in which a columnar portion HRca penetrating the stacked body LMa and a columnar portion HRcb penetrating the stacked body LMb are joined at the height position of the junction layer JL. The columnar portions HRca and HRcb can each have a tapered profile in which a diameter of a bottom surface is smaller than a diameter of an upper surface, a bowing profile in which a diameter at a predetermined height position between the upper surface and the bottom surface is increased, or the like, for example.

Each of the columnar portions HRc includes a pedestal PDc at a junction portion in the junction layer JL. The pedestal PDc has a diameter larger than the diameter of the upper surface of the columnar portion HRca arranged in the stacked body LMa. Further, each of the columnar portions HRc includes a cap layer CPc arranged in an upper end of the columnar portion HRc. The cap layer CPc, like the cap layer CP of the pillar PL, for example, has a diameter approximately equal to an outer diameter of the core layer CR of the pillar PL.

The columnar portions HRca and HRcb and the pedestal PDc are filled with an insulating layer as an insulating material such as for example. The cap layer CPc corresponds to the cap layer CP of the pillar PL, and the cap layer CPc, like the cap layer CP, is mainly made of at least one of amorphous silicon as a first material, polysilicon as a first material, and the like, for example. In other words, the cap layer CPc may be any of an amorphous silicon layer, a polysilicon layer, and a layer of mixture of those materials, for example.

The cap layer CPc as an upper layer of the columnar portion HRc produces a stronger ultraviolet-light blocking effect than an ultraviolet-light blocking effect produced by an insulating layer filled in each of the columnar portions HRca and HRcb and the pedestals PDc as a lower layer of the columnar portion HRc, for example. As described above, amorphous silicon, polysilicon, and the like, for example, that mainly make up the cap layer CPc have a property of absorbing ultraviolet light, and thus produce an ultraviolet-light blocking effect.

(Manufacturing Method of Semiconductor Memory Device)

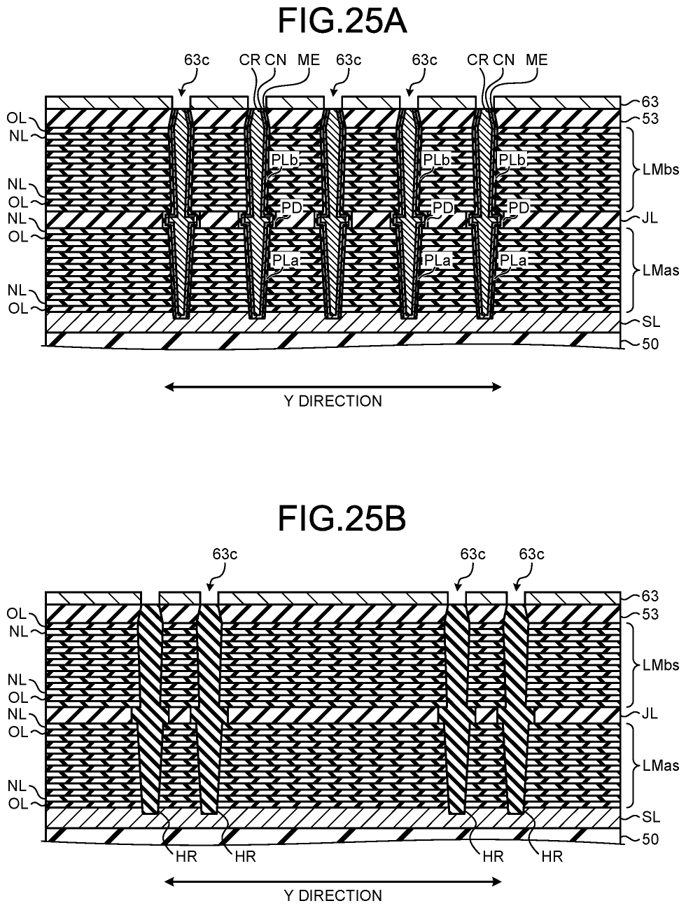

Next, an example of a manufacturing method of the semiconductor memory device 2 of the second embodiment will be described with reference to FIGS. 25A to 29B. FIGS. 25A to 29B are sectional views illustrating an example of a procedure for the manufacturing method of the semiconductor memory device 2 according to the second embodiment.

In FIGS. 25A to 29B, the figures with the same figure number and different alphabets “A” and “B” illustrate different sectional views in the same process. In FIGS. 25A to 29B, the figures with “A” illustrate sections of a portion illustrated in FIG. 23A, and the figures with “B” illustrate sections of a portion illustrated in FIG. 23B.

Also in the semiconductor memory device 2, the processes illustrated in FIGS. 4A to 10B are performed in a manner similar to the manner in the manufacturing method of the semiconductor memory device 1 of the above-described first embodiment. However, the mask film 61 illustrated in FIG. 9A is formed so as to cover only the memory holes MH in the memory region MR, and the holes HL formed near the through contact region TP are each filled with an insulating layer, thereby forming the columnar portions HR.

Below, description will be started from a status about a process of forming the columnar portion HRc from the columnar portion HR near the through contact region TP.

As illustrated in FIGS. 25A and 25B, a mask film 63 covering respective portions is formed. The mask film 63 has openings 63c above the pillar PLb in the memory region MR and above the columnar portion HR in a region sandwiched between the contact LI and the plate-shaped portion BR in the through contact region TP.

Meanwhile, at the time of formation of the pillars PLa and PLb, the memory layer ME, the channel layer CN, and the core layer CR that are formed on the insulating layer 53 where an upper surface of the columnar portion HR is exposed are removed before formation of at least the mask film 63.

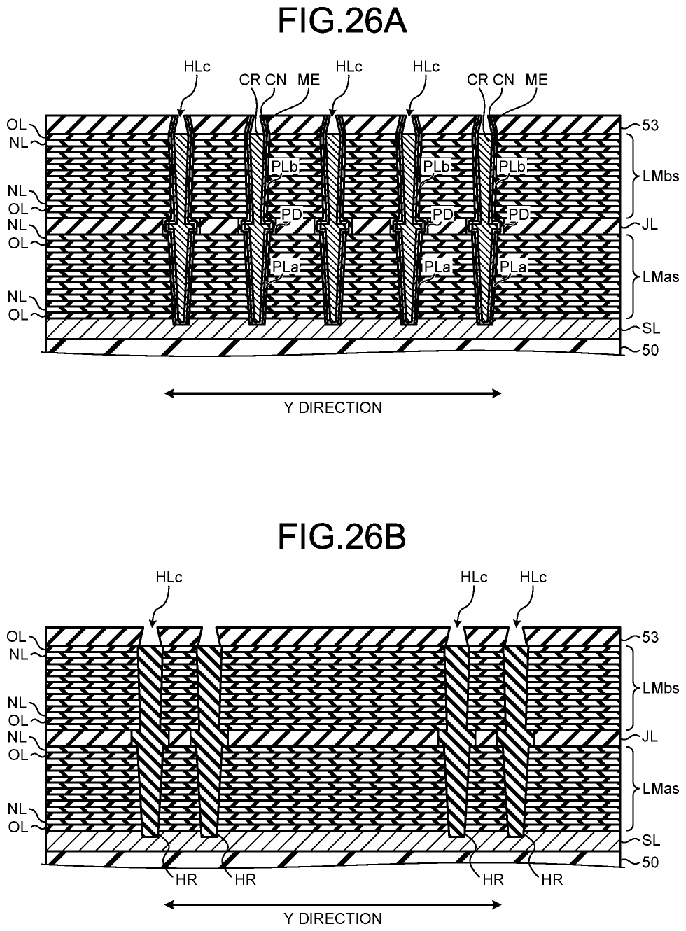

As illustrated in FIGS. 26A and 26B, upper ends of the pillar PLb and the columnar portion HR that are exposed in the openings 63c of the mask film 63 are etched back, so that the holes HLc are formed in the upper ends.

Thereafter, the mask film 63 is removed from the respective portions.

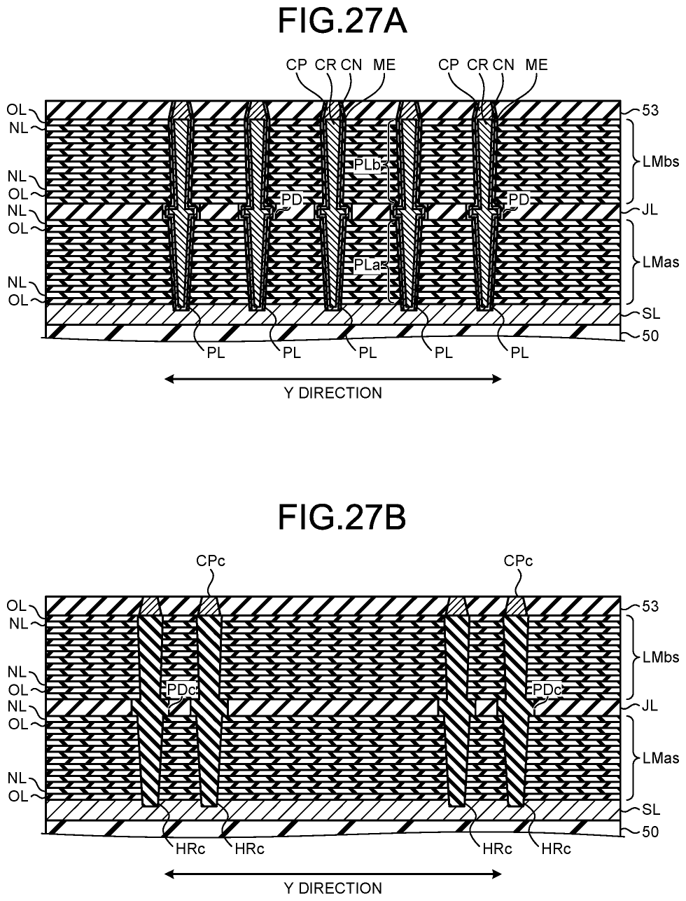

As illustrated in FIG. 27A, each of the holes HLc surrounded by the memory layer ME and the channel layer CN in the upper end of the pillar PLb is filled with an amorphous silicon layer, a polysilicon layer, or the like, thereby forming the cap layer CP having a diameter approximately equal to at least an outer diameter of the core layer CR. This results in formation of the pillar PL including the cap layer CP in its upper end.

As illustrated in FIG. 27B, each of the holes HLc in an upper end of the columnar portion HR is filled with an amorphous silicon layer, a polysilicon layer, or the like, thereby forming the cap layer CPc having a diameter approximately equal to an outer diameter of the cap layer CP on the pillar PLb. This results in formation of the columnar portion HRc including the cap layer CPc in its upper end.

Additionally, the cap layer CP in an upper portion of the pillar PL and the cap layer CPc in an upper portion of the columnar portion HRc may be layers mainly made of amorphous silicon at an initial stage of these formation, for example. Then, in the semiconductor memory device 2 provided as a finished product, a part or the whole of the amorphous silicon included in the cap layers CP and CPc may be transformed into polysilicon by being subjected to degeneration due to heat treatment or the like included in various processes to be subsequently performed.

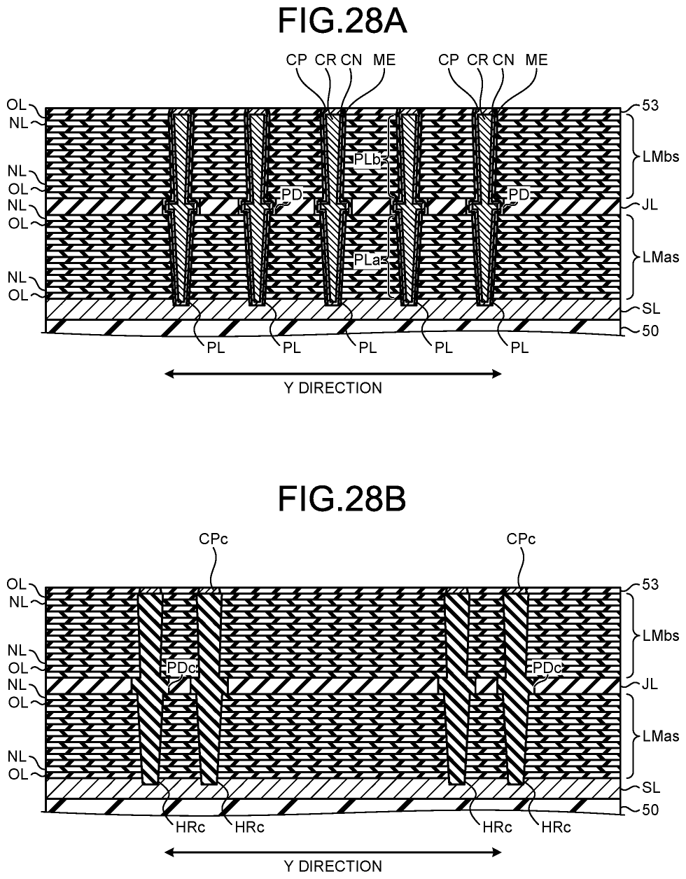

As illustrated in FIGS. 28A and 28B, the entire surface of the insulating layer 53 is etched back and thus the insulating layer 53 is made thinner. At that time, also upper portions of the cap layers CP and CPc in respective upper portions of the pillar PL and the columnar portion HRc are etched back. Further, upper portions of the columnar portions HR in the through contact region TP and the staircase region (not illustrated) are etched back.

Thereafter, slits ST and STb are formed also in the semiconductor memory device 2 in a manner similar to the manner in the manufacturing method of the semiconductor memory device 1 of the above-described first embodiment, as illustrated in FIGS. 14A and 14B. Then, as illustrated in FIGS. 15A and 15B, an insulating layer 56 is formed on a sidewall of each of the slits ST and STb.

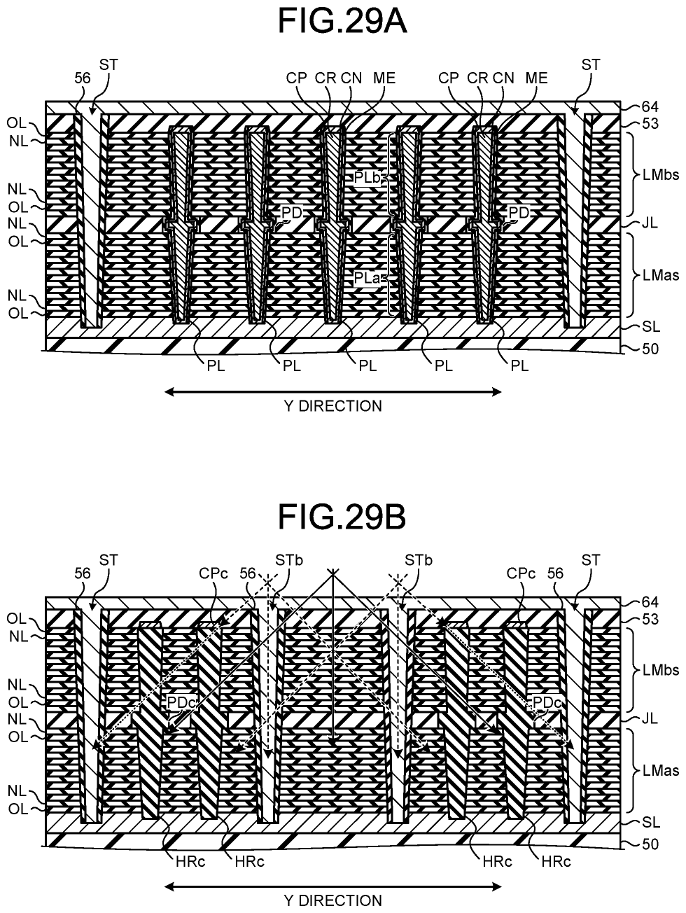

As illustrated in FIGS. 29A and 29B, a negative resist film 64 that covers all the respective portions and is filled in the slits ST and STb is formed.

As illustrated in FIG. 29B, in order to leave the negative resist film 64 in the slits STb, ultraviolet light such as DUV light is applied from above the slits STb, and the negative resist film 64 in and on the slits STb is exposed to the light.

At that time, the ultraviolet light applied to the slits STb proceeds toward the slits ST, for example, due to diffraction, interference, and the like, in some cases. However, the columnar portion HRc arranged between the slits ST and STb includes the cap layer CPc that produces a strong ultraviolet-light absorbing effect. Thus, ultraviolet light directed toward the slit ST, for example, is blocked by the columnar portion HRc, so that occurrence of spurious resolution in the negative resist film 64 filled in the slit ST is suppressed.

Thus, when the negative resist film 64 covering all the respective portions is developed, the negative resist film 64 in and on the slit STb remains while the other portions of the negative resist film 64 including the negative resist film 64 in the slit ST are removed.

Thereafter, the processes illustrated in FIGS. 18A to 22B are performed also in the semiconductor memory device 2 in a manner similar to the manner in the manufacturing method of the semiconductor memory device 1 of the above-described first embodiment. Further, there are formed an insulating member halfway penetrating the stacked body LMb (the conductive layer and the insulating layer thereon further above the stacked body LMb), the contact CC penetrating the insulating layers 53 and 51, the contact C4 penetrating the insulating layer 53, the stacked bodies LMar and LMbr, and the source line SL, the plug CH penetrating the insulating layers 54 and 53, the plug V0 penetrating the insulating layer 54, and an upper-layer wiring or the like connected to the above-mentioned components. The insulating member may be formed in parallel with formation of the slits ST and STb.

By the above-described processes, the semiconductor memory device 2 of the second embodiment is manufactured.

According to the semiconductor memory device 2 of the second embodiment, the columnar portion HRc extends in the stacking direction of the stacked bodies LMa and LMb in a position adjacent to the plate-shaped portion BR, and includes at least one of amorphous silicon and polysilicon that produces a stronger ultraviolet-light blocking effect than an ultraviolet-light blocking effect produced by the insulating layer filled in the columnar portion HR.

This suppresses spurious resolution of the negative resist film 64 in the slit ST. Therefore, it is possible to replace the insulating layers NL more surely in the other regions with the word lines WL, while leaving the insulating layers NL in a partial region of the stacked bodies LMas and LMbs.

According to the semiconductor memory device 2 of the second embodiment, the columnar portions HRc, each of which includes an insulating layer in a lower layer and includes at least one of amorphous silicon and polysilicon in an upper layer, are arranged over the entire region between the contact LI and the plate-shaped portion BR.

Thus, ultraviolet light is blocked by the cap layers CPc of the columnar portions HRc in almost all portions of an upper surface of the stacked body LMbs, for example. This can more surely suppress occurrence of spurious resolution of the negative resist film 64 in the slit ST.

Meanwhile, the cap layer CPc of the columnar portion HRc, which is arranged on the insulating layer filled in the columnar portion HRc, makes no electrical conduction with other components such as the word lines WL. Thus, even if the cap layer CPc comes into contact with the contact LI, for example, electrical influences on operations of the semiconductor memory device 2 can be suppressed.

Note that, in the above-described second embodiment, the columnar portion HR not including the cap layer CPc is arranged in a region sandwiched between two plate-shaped portions BR, for example. However, the columnar portion HRc rather than the columnar portion HR may be arranged in a region sandwiched between two plate-shaped portions BR.

As described above, consistently forming the columnar portions HRc in a position between the contacts LI arranged on both sides of the plate-shaped portion BR can reduce complication of manufacturing processes, thereby manufacturing the semiconductor memory device 2 more simply. Additionally, the columnar portions HRc rather than the columnar portions HR may be arranged also in at least a part of the staircase region SR.

Further, in the above-described second embodiment, the ultraviolet-light blocking effect is attained by arrangement of the cap layer CPc mainly made of at least one of amorphous silicon, polysilicon, and the like in the upper layer of the columnar portion HRc.

However, the cap layer in the upper layer of the columnar portion may include a metal as a first material, or may be mainly made of a metal. With such a cap layer including a metal, ultraviolet light is reflected by the metal, so that an ultraviolet-light blocking effect is attained. A cap layer including a metal, which is formed in a process separate from the process of forming the cap layer CP of the pillar PL, can produce a stronger blocking effect than a blocking effect produced by the above-described cap layer CPc, for example, because of inclusion of the metal in the cap layer. This enables thinning of a cap layer, for example.

### Other Embodiments

In the above-described first embodiment, no cap layer is formed on the columnar portion HRp. However, a cap layer (a dummy layer including amorphous silicon or polysilicon) may be formed also on the columnar portion HRp of the first embodiment, in parallel with formation of the cap layer CP of the pillar PL. This still further enhances a blocking effect.

In the above-described first and second embodiments, the staircase region SR and the through contact region TP are arranged between the plurality of memory regions MR. However, the staircase region may be arranged in one of ends in the X direction in the stacked bodies LMa and LMb, and the through contact region may be arranged outside the memory region in proximity to the staircase region.

In the above-described first and second embodiments, the contact C4 electrically connecting the word lines WL and the peripheral circuit CUA is arranged in the through contact region TP. However, the through contact region may be a region where a contact electrically connecting bit lines and the peripheral circuit, for example, is arranged, or the like.

As described above, the columnar portions HRp and HRc in the above-described first and second embodiments can be arranged in a region where a slit for inhibiting replacement and a slit for replacement may be arranged closely to each other, including a through contact region used for various purposes.

In the above-described first and second embodiments, each of the semiconductor memory devices 1 and 2 has a two-tier structure including two stacked bodies LMa and LMb. However, the semiconductor memory devices may have each a structure with a single tier or a structure with three or more tiers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first stacked body in which a plurality of first conductive layers is stacked with a first insulating layer interposed;
a second stacked body in which a plurality of second insulating layers is stacked with the first insulating layer interposed, the second stacked body being surrounded by the first stacked body as seen from a stacking direction of respective layers of the first stacked body;
a pair of first plate-shaped portions extending in the stacking direction and a first direction crossing the stacking direction, the pair of first plate-shaped portions being in contact with the second stacked body on both sides of the second stacked body in a second direction crossing the stacking direction and the first direction;
a pair of second plate-shaped portions of which longitudinal direction is in the first direction, the pair of second plate-shaped portions sandwiching the pair of first plate-shaped portions in the second direction in positions apart from the pair of first plate-shaped portions, and extending through the first stacked body in the stacking direction;
a first columnar portion extending through the first stacked body in the stacking direction in a position between the pair of second plate-shaped portions apart from the pair of first plate-shaped portions in the first direction, and forming memory cells at intersections with at least a part of the plurality of first conductive layers, respectively;
a second columnar portion extending through at least one of the first stacked body and the second stacked body in the stacking direction in a position between the pair of second plate-shaped portions arranged on both sides of the pair of first plate-shaped portions in the second direction, the second columnar portion including an insulating material; and
a third columnar portion extending through the first stacked body in the stacking direction in a position between one of the first plate-shaped portions out of the pair of first plate-shaped portions and one of the second plate-shaped portions, that faces the one of the first plate-shaped portions, out of the pair of second plate-shaped portions, the third columnar portion including a first material that has a higher ultraviolet-light blocking capability than an ultraviolet-light blocking capability of the insulating material.

2. The semiconductor memory device according to claim 1, wherein
the first columnar portion includes a channel layer extending in the stacking direction and a memory layer extending in the stacking direction on an outer periphery of the channel layer,
the third columnar portion includes the first material extending in the stacking direction and a second material extending in the stacking direction on an outer periphery of the first material,
the first material is a same material as a material included in the channel layer, and
the second material is a same material as a material included in the memory layer.

3. The semiconductor memory device according to claim 2, wherein
the second columnar portion is arranged in the position between the one of the first plate-shaped portions and the one of the second plate-shaped portions, and
the third columnar portion is arranged in a position closer to the one of the first plate-shaped portions than the second columnar portion, in the position between the one of the first plate-shaped portions and the one of the second plate-shaped portions.

4. The semiconductor memory device according to claim 3, wherein
the third columnar portion includes a plurality of third columnar portions, and
the plurality of third columnar portions is arrayed along the one of the first plate-shaped portions in the first direction in the position closer to the one of first plate-shaped portions.

5. The semiconductor memory device according to claim 1, wherein
the third columnar portion includes a plurality of third columnar portions, and
the plurality of third columnar portions includes another third columnar portion that extends through the first stacked body in the stacking direction in a position between the other of the first plate-shaped portions out of the pair of first plate-shaped portions and the other of the second plate-shaped portions, that faces the other of the first plate-shaped portions, out of the pair of second plate-shaped portions.

6. The semiconductor memory device according to claim 2, wherein
the second columnar portion is arrayed in a position closer to the one of the second plate-shaped portions than the third columnar portion, in the position between the one of the first plate-shaped portions and the one of the second plate-shaped portions.

7. The semiconductor memory device according to claim 6, wherein
the second columnar portion includes a plurality of second columnar portions, and
the plurality of second columnar portions is arrayed along the one of the second plate-shaped portions in the first direction in the position closer to the one of the second plate-shaped portions.

8. The semiconductor memory device according to claim 1, wherein
the third columnar portion includes a same material as the insulating material in a lower layer and includes the first material in an upper layer.

9. The semiconductor memory device according to claim 8, wherein
the first columnar portion includes a channel layer extending in the stacking direction and a memory layer extending in the stacking direction on an outer periphery of the channel layer in a lower layer, and includes at least a same material as the first material in an upper layer.

10. The semiconductor memory device according to claim 8, wherein
the second columnar portion includes a plurality of second columnar portions,
the plurality of second columnar portions is arranged distributed from each other in a position between the pair of first plate-shaped portions,
the third columnar portion includes a plurality of third columnar portions, and
the plurality of third columnar portions is arranged distributed from each other in the position between the one of the first plate-shaped portions and the one of the second plate-shaped portions and in a position between the other of the first plate-shaped portions out of the pair of first plate-shaped portions and the other of the second plate-shaped portions, that faces the other of the first plate-shaped portions, out of the pair of second plate-shaped portions.

11. The semiconductor memory device according to claim 10, wherein
the plurality of second columnar portions is arranged in the position between the pair of first plate-shaped portions while the plurality of third columnar portions is not arranged in the position between the pair of first plate-shaped portions, and
the plurality of third columnar portions is arranged in the position between the one of the first plate-shaped portions and the one of the second plate-shaped portions and in the position between the other of the first plate-shaped portions and the other of the second plate-shaped portions while the plurality of second columnar portions is not arranged in the position between the one of the first plate-shaped portions and the one of the second plate-shaped portions and in the position between the other of the first plate-shaped portions and the other of the second plate-shaped portions.

12. The semiconductor memory device according to claim 1, wherein
the first material includes at least one of amorphous silicon or polysilicon.

13. A semiconductor memory device comprising:
a first stacked body in which a plurality of first conductive layers is stacked with a first insulating layer interposed;
a second stacked body in which a plurality of second insulating layers is stacked with the first insulating layer interposed, the second stacked body being surrounded by the first stacked body as seen from a stacking direction of respective layers of the first stacked body;
a pair of first plate-shaped portions extending in the stacking direction and a first direction crossing the stacking direction, the pair of first plate-shaped portions being in contact with the second stacked body on both sides of the second stacked body in a second direction crossing the stacking direction and the first direction;
a pair of second plate-shaped portions of which longitudinal direction is in the first direction, the pair of second plate-shaped portions sandwiching the pair of first plate-shaped portions in the second direction in positions apart from the pair of first plate-shaped portions, and extending through the first stacked body in the stacking direction;
a first columnar portion extending through the first stacked body in the stacking direction in a position between the pair of second plate-shaped portions apart from the pair of first plate-shaped portions in the first direction, and forming memory cells at intersections with at least a part of the plurality of first conductive layers, respectively;
a second columnar portion extending through at least one of the first stacked body and the second stacked body in the stacking direction in a position between the pair of second plate-shaped portions arranged on both sides of the pair of first plate-shaped portions in the second direction, the second columnar portion including a structure different from a structure of the first columnar portion; and
a third columnar portion extending through the first stacked body in the stacking direction at a position beside one of the first plate-shaped portions out of the pair of first plate-shaped portions in the second direction, the third columnar portion including a same stacked structure as a stacked structure of the first columnar portion.

14. The semiconductor memory device according to claim 13, wherein
the first columnar portion includes a channel layer extending in the stacking direction and a memory layer extending in the stacking direction on an outer periphery of the channel layer,
the third columnar portion includes a first material extending in the stacking direction and a second material extending in the stacking direction on an outer periphery of the first material,
the first material is a same material as a material included in the channel layer, and
the second material is a same material as a material included in the memory layer.

15. The semiconductor memory device according to claim 14, wherein
the second columnar portion includes an insulating material, and
the first material has a higher ultraviolet-light blocking capability than an ultraviolet-light blocking capability of the insulating material.

16. The semiconductor memory device according to claim 13, wherein
the third columnar portion is arranged in a position between the one of the first plate-shaped portions and one of the second plate-shaped portions, that faces the one of the first plate-shaped portions, out of the pair of second plate-shaped portions, and
the second columnar portion is arranged in a position closer to the one of the second plate-shaped portions than the third columnar portion, in the position between the one of the first plate-shaped portions and the one of the second plate-shaped portions.

17. The semiconductor memory device according to claim 16, wherein
the third columnar portion includes a plurality of third columnar portions, and
the plurality of third columnar portions includes another third columnar portion that extends through the second stacked body in the stacking direction in a position between the pair of first plate-shaped portions.

18. A semiconductor memory device comprising:
a first stacked body in which a plurality of first conductive layers is stacked with a first insulating layer interposed, the first stacked body including a first region in which a plurality of memory cells is arranged;
a second stacked body in which a plurality of second insulating layers is stacked with the first insulating layer interposed, in a second region different from the first region, the second stacked body being surrounded by the first stacked body as seen from a stacking direction of respective layers of the first stacked body;
a pair of first plate-shaped portions extending in the stacking direction and a first direction crossing the stacking direction, the pair of first plate-shaped portions being in contact with the second stacked body on both sides of the second stacked body in a second direction crossing the stacking direction and the first direction;
a pair of second plate-shaped portions of which longitudinal direction is in the first direction, the pair of second plate-shaped portions extending through the first stacked body in the stacking direction in the first region and the second region, and extending in the first direction on both sides of the pair of first plate-shaped portions in the second direction in positions apart from the pair of first plate-shaped portions in the second region; and
a columnar portion extending through the first stacked body in the stacking direction in a position between one of the first plate-shaped portions out of the pair of first plate-shaped portions and one of the second plate-shaped portions, that faces the one of the first plate-shaped portions, out of the pair of second plate-shaped portions, the columnar portion including an insulating material in a lower layer and including a first material that has a higher ultraviolet-light blocking capability than an ultraviolet-light blocking capability of the insulating material, in an upper layer.

19. The semiconductor memory device according to claim 18, wherein
the columnar portion includes a plurality of columnar portions, and
the plurality of columnar portions is arranged distributed from each other in the position between the one of the first plate-shaped portions and the one of the second plate-shaped portions.

20. The semiconductor memory device according to claim 18, wherein
the first material includes at least one of amorphous silicon or polysilicon.
